(19) United States
(12) Patent Application Publication
(10) Pub. No.: US 2025/0056984 A1
(43) Pub. Date: Feb. 13, 2025

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Mengqi WANG, Beijing (CN); Shilong WANG, Beijing (CN); Ziyang YU, Beijing (CN); Zhiliang JIANG, Beijing (CN)

(21) Appl. No.: 18/687,829

(22) PCT Filed: Jun. 9, 2023
(86) PCT No.: PCT/CN2023/099495

§ 371 Date: Feb. 29, 2024

(30) Foreign Application Priority Data
Jun. 15, 2022 (CN) 202210670468.6

(51) Int. Cl. H10K 59/131; H10K 59/121

(52) U.S. Cl. CPC H10K 59/131; H10K 59/1213

(57) ABSTRACT

A display substrate and a display apparatus. The display substrate comprises a display region (100); the display region (100) comprises a base (101), a driving circuit layer (102) and a light-emitting structure layer (103); the driving circuit layer (102) comprises a plurality of circuit units, data signal lines (60), data connecting lines (70), low-voltage power supply lines (80), and power supply traces (90); the light-emitting structure layer (103) comprises a plurality of light-emitting devices; the circuit units comprise pixel driving circuits; the data signal lines (60) are configured to provide data signals for the pixel driving circuits; the low-voltage power supply lines (80) are configured to continuously provide low power supply voltage signals for the light-emitting devices; the data connecting lines (70) are connected to the data signal lines (60); and the power supply traces (90) are connected to the low-voltage power supply lines (80).

### CROSS-REFERENCE TO RELATED APPLICATIONS

The present application is a U.S. National Phase Entry of International Application No. PCT/CN2023/099495 having an international filing date of Jun. 9, 2023, which claims priority to Chinese Patent Application No. 202210670468.6, filed to the CNIPA on Jun. 15, 2022 and entitled “Display Substrate and Display Apparatus”, contents of the above-identified applications should be regarded as being incorporated herein by reference.

### TECHNICAL FIELD

The present disclosure relates to, but is not limited to, the field of display technologies, and more particularly, to a display substrate and a display apparatus.

### BACKGROUND

An Organic Light Emitting Diode (OLED for short) and a Quantum dot Light Emitting Diode (QLED for short) are active light emitting display devices and have advantages such as self-luminescence, a wide viewing angle, a high contrast ratio, low power consumption, an extremely high response speed, lightness and thinness, flexibility, and a low cost. With constant development of display technologies, a flexible display apparatus (Flexible Display) in which an OLED or a QLED is used as a light emitting device and signal control is performed through a Thin Film Transistor (TFT) has become a mainstream product in the field of display at present.

### SUMMARY

The following is a summary of subject matters described herein in detail. The summary is not intended to limit the scope of protection of claims.

In one aspect, the present disclosure provides a display substrate including a display region, wherein the display region includes a drive circuit layer disposed on a base substrate and a light emitting structure layer disposed at a side of the drive circuit layer away from the base substrate, the drive circuit layer includes a plurality of circuit units, a plurality of data signal lines, a plurality of data connection lines, a plurality of low-voltage power supply lines, and a plurality of power supply traces, the light emitting structure layer includes a plurality of light emitting devices, the circuit units include pixel drive circuits, the data signal lines are configured to provide data signals to the pixel drive circuits, the low-voltage power supply lines are configured to continuously provide low power supply voltage signals to the light emitting devices; the data connection lines are connected with the data signal lines, and the power supply traces are connected with the low-voltage power supply lines.

In an exemplary implementation mode, a data connection line includes a first connection line extending along a first direction and a second connection line extending along a second direction, the first connection line is connected with the second connection line, a power supply trace includes a first power supply trace extending along the first direction and a second power supply trace extending along the second direction, the first power supply trace is connected with the second power supply trace, the first direction and the second direction intersect; on a plane parallel to the base substrate, the display region at least includes a first region provided with the first connection line, at least one circuit unit of the first region includes the first connection line, the first power supply trace, and the second power supply trace, a data signal line and a low-voltage power supply line are in a shape of a line extending along the second direction, the first connection line is connected with the data signal line, the second power supply trace is disposed between the low-voltage power supply line and the data signal line, and the second power supply trace is connected with the low-voltage power supply line.

In an exemplary implementation mode, the drive circuit layer includes a plurality of conductive layers sequentially disposed on the base substrate; the first connection line and the second connection line are disposed in a same conductive layer, and the first connection line and the data signal line are disposed in different conductive layers; in at least one circuit unit of the first region, the first connection line is connected with the data signal line through a first connection hole.

In an exemplary implementation mode, the drive circuit layer includes a plurality of conductive layers sequentially disposed on the base substrate; the first power supply trace and the second power supply trace are disposed in a same conductive layer, and the second power supply trace and the low-voltage power supply line are disposed in different conductive layers; in at least one circuit unit of the first region, the second power supply line is connected with the low-voltage power supply line through a second connection hole.

In an exemplary implementation mode, at least one circuit unit of the first region further includes a power supply connection electrode, the power supply connection electrode is disposed at a side of the second power supply trace away from the data signal line and connected with the second power supply trace, an orthographic projection of the power supply connection electrode on the base substrate is at least partially overlapped with an orthographic projection of the low-voltage power supply line on the base substrate, and the power supply connection electrode is connected with the low-voltage power supply line through a second connection hole.

In an exemplary implementation mode, first connection lines in circuit units adjacent in the first direction are connected with each other, and first power supply traces in the circuit units adjacent in the first direction are connected with each other.

In an exemplary implementation mode, in the first region, second power supply traces in circuit units adjacent in the second direction are disposed at intervals, and the first connection line is disposed between second power supply traces adjacent in the second direction.

In an exemplary implementation mode, at least one circuit unit of the first region further includes a second compensation line extending along the second direction, the second compensation line is disposed at a side of the second power supply trace away from the data signal line, the second compensation line is connected with the first power supply trace, second compensation lines in circuit units adjacent in the second direction are disposed at intervals, and the first connection line is disposed between second compensation lines adjacent in the second direction.

In an exemplary implementation mode, on a plane parallel to the base substrate, the display region further includes a second region provided with the second connection line, the second connection line is included in at least one circuit unit of the second region, and second connection lines in circuit units adjacent in the second direction are connected with each other.

In an exemplary implementation mode, at least one circuit unit of the second region includes two second connection lines, the two second connection lines include a first side connection line and a second side connection line, the first side connection line is disposed between the low-voltage power supply line and the data signal line, and the second side connection line is disposed at a side of the low-voltage power supply line away from the data signal line.

In an exemplary implementation mode, at least one circuit unit of the second region further includes a dummy connection electrode, the dummy connection electrode is disposed at a side of the second side connection line close to the first side connection line and connected with the second side connection line, and an orthographic projection of the dummy connection electrode on the base substrate is at least partially overlapped with an orthographic projection of the low-voltage power supply line on the base substrate.

In an exemplary implementation mode, in at least one unit column including a circuit unit of the first region and a circuit unit of the second region, a second power supply trace of the first region and a first side connection line of the second region are located on a same straight line extending along the second direction, a second compensation line of the first region and a second side connection line of the second region are located on a same straight line extending along the second direction, and a power supply connection electrode of the first region and a dummy connection electrode of the second region are located on a same straight line extending along the second direction; in at least one unit row including a circuit unit of the first region and a circuit unit of the second region, a power supply connection electrode of the first region and a dummy connection electrode of the second region are located on a same straight line extending along the first direction.

In an exemplary implementation mode, at least one circuit unit of the second region further includes at least two first compensation lines extending along the first direction, the at least two first compensation lines include at least one first side compensation line and at least one second side compensation line, a first end of the first side compensation line is connected with the first side connection line, a second end of the first side compensation line extends toward a direction close to the second side connection line, a first end of the second side compensation line is connected with the second side connection line, and a second end of the second side compensation line extends toward a direction close to the first side connection line.

In an exemplary implementation mode, in at least one unit row including a circuit unit of the first region and a circuit unit of the second region, a first power supply trace of the first region and a first side compensation line of the second region are located on a same straight line extending along the first direction, and a first connection line of the first region and a second side compensation line of the second region are located on a same straight line extending along the first direction.

In an exemplary implementation mode, on a plane parallel to the base substrate, the display region further includes a third region that is not overlapped with orthographic projections of the first connection line and the second connection line on the base substrate, and at least one circuit unit of the third region includes the first power supply trace and the second power supply trace, and the second power supply trace is connected with the low-voltage power supply line through a second connection hole.

In an exemplary implementation mode, the second power supply trace is disposed between the low-voltage power supply line and the data signal line, at least one circuit unit of the third region further includes a power supply connection electrode, the power supply connection electrode is disposed at a side of the second power supply trace away from the data signal line and connected with the second power supply trace, an orthographic projection of the power supply connection electrode on the base substrate is at least partially overlapped with an orthographic projection of the low-voltage power supply line on the base substrate, and the power supply connection electrode is connected with the low-voltage power supply line through the second connection hole.

In an exemplary implementation mode, first power supply traces in circuit units adjacent in the first direction are connected with each other, and second power supply traces in circuit units adjacent in the second direction are connected with each other.

In an exemplary implementation mode, at least one circuit unit of the third region further includes a first compensation line extending along the first direction and a second compensation line extending along the second direction, first compensation lines in circuit units adjacent in in the first direction are connected with each other, second compensation lines in circuit units adjacent in the second direction are connected with each other, the first compensation line is connected with the second power supply trace, the second compensation line is connected with the first power supply trace, and the first compensation line is connected with the second compensation line.

In an exemplary implementation mode, in at least one unit row including a circuit unit of the first region and a circuit unit of the third region, a first connection line of the first region and a first compensation line of the third region are located on a same straight line extending along the first direction; in at least one unit column including a circuit unit of the first region and a circuit unit of the third region, a second compensation line of the first region and a second compensation line of the third region are located on a same straight line extending along the second direction.

In an exemplary implementation mode, on a plane parallel to the base substrate, the display region further includes: a second region provided with the second connection line, and a third region that is not overlapped with orthographic projections of the first connection line and the second connection line on the base substrate; in at least one unit row including a circuit unit of the first region, a circuit unit of the second region, and a circuit unit of the third region, a first power supply trace of the first region, a first side compensation line in a first compensation line of the second region, and a first power supply trace of the third region are located on a same straight line extending along the first direction, a first connection line of the first region, a second side compensation line in a first compensation line of the second region, and a first compensation line of the third region are located on a same straight line extending along the first direction, a power supply connection electrode of the first region, a dummy connection electrode of the second region, and a power supply connection electrode of the third region are located on a same straight line extending along the first direction; in at least one unit column including a circuit unit of the first region, a circuit unit of the second region, and a circuit unit of the third region, a second power supply trace of the first region, a first side connection line in a second connection line of the second region, and a second power supply trace of the third region are located on a same straight line extending along the second direction, a second compensation line of the first region, a second side connection line in a second connection line of the second region, and a second compensation line of the third region are located on a same straight line extending along the second direction, and a power supply connection electrode of the first region, a dummy connection electrode of the second region, and a power supply connection electrode of the third region are located on a same straight line extending along the second direction.

In an exemplary implementation mode, the display substrate further includes a bonding region located at a side of the display region in the second direction, the bonding region at least includes a bonding lead, a first power supply connection line, and a first power supply pin, a first end of the first power supply connection line is connected with the low-voltage power supply line through a via, a second end of the second power supply connection line, after extending toward a direction away from the display region, is connected with the first power supply pin, and the first power supply pin is connected with the bonding lead through a via.

In an exemplary implementation mode, the display substrate further includes an upper bezel region located at a side of the display region in an opposite direction of the second direction, the upper bezel region at least includes an upper bezel lead, a second power supply connection strip, a second power supply connection line, and a second power supply pin, a first end of the second power supply connection strip is connected with the low-voltage power supply line through a via, a second end of the second power supply connection strip is connected with a first end of the second power supply connection line, a second end of the second power supply connection line, after extending toward a direction away from the display region, is connected with the second power supply pin, and the second power supply pin is connected with the upper bezel lead through a via.

In an exemplary implementation mode, the display substrate further includes a side bezel region located at a side or two sides of the display region in the first direction, wherein the side bezel region at least includes a side bezel lead, a third power supply connection line, and a third power supply pin, a first end of the third power supply connection line is connected with the power supply trace through a via, a second end of the third power supply connection line, after extending toward a direction away from the display region, is connected with the third power supply pin, and the third power supply pin is connected with the side bezel lead through a via.

In an exemplary implementation mode, the drive circuit layer further includes a plurality of circuit units, a circuit unit includes a pixel drive circuit, the pixel drive circuit at least includes a storage capacitor and a plurality of transistors; on a plane perpendicular to the display substrate, the drive circuit layer includes a semiconductor layer, a first conductive layer, a second conductive layer, a third conductive layer, a fourth conductive layer, and a fifth conductive layer disposed sequentially on the base substrate, wherein the semiconductor layer at least includes active layers of the plurality of transistors, the first conductive layer at least includes gate electrodes of the plurality of transistors, and a first electrode plate of the storage capacitor, the second conductive layer at least includes a second electrode plate of the storage capacitor, the third conductive layer at least includes first electrodes and second electrodes of the plurality of transistors, the fourth conductive layer at least includes the data signal line and the low-voltage power supply line, and the fifth conductive layer at least includes the data connection line and the power supply trace.

In an exemplary implementation mode, the third conductive layer further includes a first power supply line configured to continuously provide a high power supply voltage signal to the pixel drive circuit, an orthographic projection of the low-voltage power supply line on the base substrate and an orthographic projection of the first power supply line on the base substrate are at least partially overlapped and have a first overlapping area, the orthographic projection of the first power supply line on the base substrate has a first area, and the first overlapping area is greater than 0.8* the first area.

In an exemplary implementation mode, the second conductive layer further includes a second initial signal line configured to provide a second initial signal to the pixel drive circuit, an orthographic projection of a first connection line in the data connection line on the base substrate and an orthographic projection of the second initial signal line on the base substrate are at least partially overlapped and have a second overlapping area, the orthographic projection of the first connection line on the base substrate has a second area, and the second overlapping area is greater than 0.8* the second area.

In another aspect, the present disclosure also provides a display apparatus, including the display substrate described above.

Other aspects of the present disclosure may be comprehended after drawings and detailed description are read and understood.

### BRIEF DESCRIPTION OF DRAWINGS

Accompany drawings are used for providing further understanding of technical solutions of the present disclosure, and constitute a part of the description. The accompany drawings, together with embodiments of the present disclosure, are used for explaining the technical solutions of the present disclosure, and do not constitute limitations on the technical solutions of the present disclosure.

FIG. 1 is a schematic diagram of a structure of a display apparatus.

FIG. 2 is a schematic diagram of a structure of a display substrate.

FIG. 3 is a schematic diagram of a planar structure of a display region in a display substrate.

FIG. 4 is a schematic diagram of a sectional structure of a display region in a display substrate.

FIG. 5 is a schematic diagram of an equivalent circuit of a pixel drive circuit.

FIG. 6 is a schematic diagram of a planar structure of a display substrate according to an exemplary embodiment of the present disclosure.

FIG. 7 is a schematic diagram of an arrangement of data connection lines according to an exemplary embodiment of the present disclosure.

FIG. 8 is a schematic diagram of a planar structure of another display substrate according to an exemplary embodiment of the present disclosure.

FIG. 9 is a schematic diagram of an arrangement of a data connection line and a power supply trace according to an exemplary embodiment of the present disclosure.

FIG. 10 is a schematic diagram of partition of a display region according to an exemplary embodiment of the present disclosure.

FIGS. 11a to 11c are schematic diagrams of a structure of three regions according to an exemplary embodiment of the present disclosure.

FIG. 12 is a schematic diagram obtained after a pattern of a semiconductor layer is formed according to an embodiment of the present disclosure.

FIG. 13a and FIG. 13b are schematic diagrams after a pattern of a first conductive layer is formed according to an embodiment of the present disclosure.

FIG. 14a and FIG. 14b are schematic diagrams after a pattern of a second conductive layer is formed according to an embodiment of the present disclosure.

FIG. 15 is a schematic diagram obtained after a pattern of a fourth insulation layer is formed according to an embodiment of the present disclosure.

FIG. 16a and FIG. 16b are schematic diagrams after a pattern of a third conductive layer is formed according to an embodiment of the present disclosure.

FIG. 17 is a schematic diagram after forming a pattern of a first planarization layer according to an embodiment of the present disclosure.

FIG. 18a to FIG. 18d are schematic diagrams after a pattern of a fourth conductive layer is formed according to an embodiment of the present disclosure.

FIGS. 19a to 19c are schematic diagrams after a pattern of a second planarization layer is formed according to an embodiment of the present disclosure.

FIG. 20a to FIG. 20f are schematic diagrams after a pattern of a fifth conductive layer is formed according to an embodiment of the present disclosure.

FIGS. 21a to 21c are schematic diagrams after a pattern of a third planarization layer is formed according to an embodiment of the present disclosure.

FIG. 22a to FIG. 22d are schematic diagrams after a pattern of an anode conductive layer is formed according to an embodiment of the present disclosure.

FIG. 23 is a schematic diagram of a planar structure of a power supply trace according to an exemplary embodiment of the present disclosure.

FIG. 24 is a schematic diagram of a connection between a power supply trace and a bonding lead according to an exemplary embodiment of the present disclosure.

FIG. 25 is a schematic diagram of a connection between a power supply trace and an upper bezel lead according to an exemplary embodiment of the present disclosure.

FIG. 26 is a schematic diagram of a connection between a power supply trace and a side bezel lead according to an exemplary embodiment of the present disclosure.

Reference signs are described as follows.

| | | |
|---|---|---|
| 11-first active layer; | 12-second active layer; | 13-third active layer; |
| 14-fourth active layer; | 15-fifth active layer; | 16-sixth active layer; |
| 17-seventh active layer; | 21-first scan signal line; | 21-1 - gate block; |
| 22-second scan signal line | 23-light emitting control line; | 24-first electrode plate; |
| 31-first initial signal line; | 32-second initial signal line; | 33-second electrode plate; |
| 34-electrode plate connection line; | 35-shielding electrode; | 36-opening; |
| 41-first connection electrode; | 42-second connection electrode; | 43-third connection electrode; |
| 44-fourth connection electrode; | 45-fifth connection electrode; | 46-first power supply line; |
| 47-initial connection line; | 51-first anode connection electrode; | 53-second anode connection electrode; |
| 60-data signal line; | 61-data connection electrode; | 70-data connection line; |
| 71-first connection line; | 72-second connection line; | 73-dummy connection electrode; |
| 80-second power supply line; | 90-power supply trace; | 91-first power supply trace; |
| 92-second power supply trace; | 93-power supply connection electrode; | 100-display region; |
| 100A-first region; | 100B-second region; | 100C-third region; |
| 101-base substrate; | 102-drive circuit layer; | 103-light emitting structure layer; |
| 104-encapsulation structure layer; | 110-first compensation line; | 120-second compensation line; |
| 200-bonding region; | 201-lead region; | 210-leading out line; |
| 300-bezel region; | 301-anode; | 302-pixel definition layer; |
| 303-organic emitting layer; | 304-cathode; | 310-upper bezel region; |
| 320-side bezel region; | 401-first encapsulation layer; | 402-second encapsulation layer; |
| 403-third encapsulation layer; | 510-bonding lead; | 511-first power supply connection line; |
| 512-first power supply pin; | 520-upper bezel lead; | 521-second power connection strip; |
| 522-second power supply connection line; | 523-second power supply pin; | 530-side bezel lead; |
| 531-third power supply connection line; | 532-third power supply pin. | |

### DETAILED DESCRIPTION

To make the objectives, the technical solutions, and advantages of the present disclosure clearer, the embodiments of the present disclosure will be described in detail below in combination with the accompany drawings. It is to be noted that implementation modes may be implemented in multiple different forms. Those of ordinary skills in the art may easily understand such a fact that modes and contents may be transformed into various forms without departing from the purpose and scope of the present disclosure. Therefore, the present disclosure should not be explained as being limited to contents recorded in following implementation modes only. The embodiments in the present disclosure and features in the embodiments may be randomly combined with each other if there is no conflict.

Scales of the drawings in the present disclosure may be used as a reference in actual processes, but are not limited thereto. For example, a width-length ratio of a channel, a thickness and a pitch of each film layer, and a width and a pitch of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limitations on numbers but only to avoid confusion between constituent elements.

In the specification, for convenience, expressions “central”, “above”, “below”, “front”, “back”, “vertical”, “horizontal”, “top”, “bottom”, “inside”, “outside”, etc., indicating orientations or positional relationships are used to illustrate positional relationships between constituent elements with reference to the drawings, not to indicate or imply that a referred apparatus or element must have a specific orientation and be structured and operated with the specific orientation but only to easily and simply describe the specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, an “electrical connection” includes a case that constituent elements are connected together through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulation film” may be replaced with an “insulation layer” sometimes.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc.

In the present disclosure, “about” refers to that a boundary is not defined so strictly and numerical values within a range of process and measurement errors are allowed.

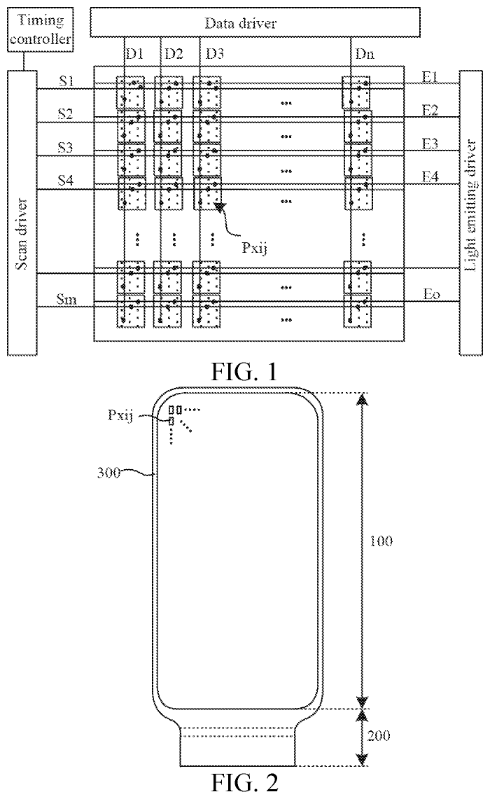

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include multiple sub-pixels Pxij, wherein i and j may be natural numbers. At least one sub-pixel Pxij may include a circuit unit and a light emitting device connected with the circuit unit, wherein the circuit unit may at least include a pixel drive circuit, and the pixel drive circuit is connected with a scan signal line, a light emitting signal line, and a data signal line, respectively. In an exemplary implementation mode, the timing controller may provide a grayscale value and a control signal suitable for a specification of the data signal driver to the data signal driver, may provide a clock signal, a scan start signal, etc. suitable for a specification of the scan driver to the scan driver, and may provide a clock signal, an emission stop signal, etc. suitable for a specification of the light emitting driver to the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signal to be provided to the scan signal lines S1, S2, S3, . . . , and Sm by receiving the clock signal and the scan start signal etc. from the timing controller. For example, the scan driver may sequentially provide a scan signal with an on level pulse to the scan signal lines S1 to Sm. For example, the scan driver may be constructed in a form of a shift register and generate a scan signal in a manner of sequentially transmitting a scan start signal provided in a form of an on level pulse to a next-stage circuit under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

FIG. 2 is a schematic diagram of a structure of a display substrate. As shown in FIG. 2, the display substrate may include a display region 100, a bonding region 200 located at a side of the display region 100, and a bezel region 300 located at another side of the display region 100. In an exemplary implementation mode, the display region 100 may be a plat region, including a plurality of sub-pixels Pxij that constitute a pixel array, wherein the plurality of sub-pixels Pxij are configured to display a dynamic picture or a static image, and the display region 100 may be referred to as an Active Area (AA). In an exemplary implementation mode, the display substrate may be a flexible substrate, so that the display substrate may be deformable, for example, curled, bent, folded, or rolled.

In an exemplary implementation mode, the bonding region 200 may include a fanout region, a bending region, a drive chip region, and a bonding pin region sequentially disposed along a direction away from the display region, wherein the fanout region is connected to the display region 100 and at least includes data fanout lines, and multiple data fanout lines are configured to connect a data signal line of the display region in a fanout trace manner. The bending region is connected to the fanout region and may include a composite insulation layer provided with a groove, and is configured to enable the bonding region to be bent to a back of the display region. The drive chip region may include an Integrated Circuit (IC for short), and the Integrated Circuit is configured to be connected with multiple data fanout lines. The bonding pin region may include a Bonding Pad, and the Bonding Pad is configured to be bonded and connected with an external Flexible Printed Circuit (FPC for short).

In an exemplary implementation mode, the bezel region 300 may include a circuit region, a power supply line region, a crack dam region, and a cutting region which are sequentially disposed along the direction away from the display region 100. The circuit region is connected to the display region 100 and may at least include a gate drive circuit which is connected with a first scan line, a second scan line, and a light emitting control line of a pixel drive circuit in the display region 100. The power supply line region is connected to the circuit region and may at least include a bezel power supply lead line that extends along a direction parallel to an edge of the display region and is connected with a cathode in the display region 100. The crack dam region is connected to the power supply line region and may at least include a plurality of cracks disposed on the composite insulation layer. The cutting region is connected to the crack dam region and may at least include a cutting groove disposed on the composite insulation layer, wherein the cutting groove is configured for respectively cutting along the cutting groove by a cutting device after all film layers of the display substrate are manufactured.

In an exemplary implementation mode, the fanout region in the bonding region 200 and the power supply line region in the bezel region 300 may be provided with a first dam spacer and a second dam spacer, the first dam spacer and the second dam spacer may extend along a direction parallel to an edge of the display region, thus forming an annular structure surrounding the display region 100, wherein the edge of the display region is an edge at a side of the display region, the bonding region, or the bezel region.

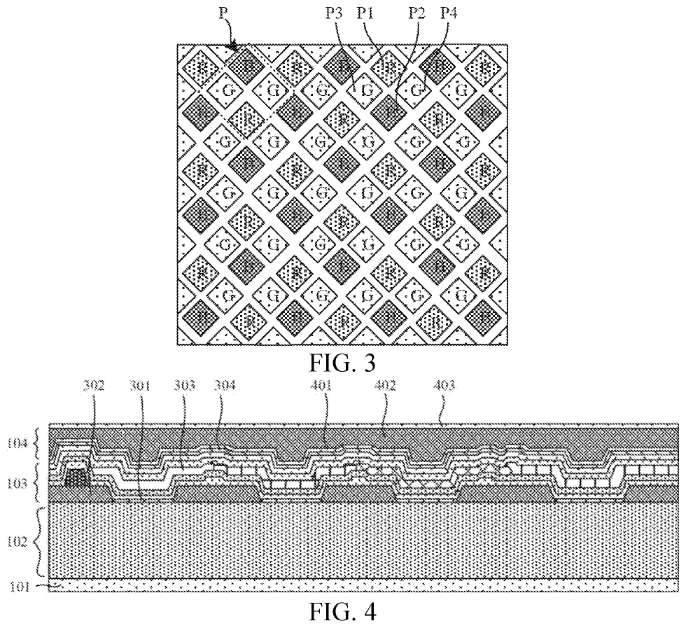

FIG. 3 is a schematic diagram of a planar structure of a display region in a display substrate. As shown in FIG. 3, the display substrate may include a plurality of pixel units P arranged in a matrix. At least one pixel unit P may include a first sub-pixel P1 emitting light of a first color, a second sub-pixel P2 emitting light of a second color, and a third sub-pixel P3 and a fourth sub-pixel P4 emitting light of a third color. Each sub-pixel may include a circuit unit and a light emitting device, wherein the circuit unit may at least include a pixel drive circuit which is connected with a scan signal line, a data signal line, and a light emitting signal line respectively, and the pixel drive circuit is configured to receive a data voltage transmitted by the data signal line and output a corresponding current to the light emitting device under control of the scan signal line and the light emitting signal line. The light emitting device in each sub-pixel is connected with a pixel drive circuit of a sub-pixel where the light emitting device is located, and is configured to emit light with corresponding brightness in response to a current output by the pixel drive circuit of the sub-pixel where the light emitting device is located.

In an exemplary implementation mode, the first sub-pixel P1 may be a red sub-pixel (R) emitting red light, the second sub-pixel P2 may be a blue sub-pixel (B) emitting blue light, and the third sub-pixel P3 and the fourth sub-pixel P4 may be green sub-pixels (G) emitting green light. In an exemplary implementation mode, a shape of a sub-pixel may be a rectangle, a diamond, a pentagon, or a hexagon. The four sub-pixels may be arranged in a manner of diamond to form an RGBG pixel arrangement. In another exemplary embodiment, the four sub-pixels may be arranged side by side horizontally, side by side vertically, or in a manner to form a square, etc., which is not limited here in the present disclosure.

In an exemplary implementation mode, a pixel unit may include three sub-pixels, and the three sub-pixels may be arranged side by side horizontally, side by side vertically, or in a manner like a Chinese character “ [symbol] ”, which is not limited here in the present disclosure.

FIG. 4 is a schematic diagram of a sectional structure of a display region in a display substrate, illustrating a structure of four sub-pixels in the display region. As shown in FIG. 4, on a plane perpendicular to the display substrate, the display substrate may include a drive circuit layer 102 disposed on a base substrate 101, a light emitting structure layer 103 disposed at a side of the drive circuit layer 102 away from the base substrate 101, and an encapsulation structure layer 104 disposed at a side of the light emitting structure layer 103 away from the base substrate 101. In some possible implementation modes, the display substrate may include another film layer, such as a touch structure layer, which is not limited here in the present disclosure.

In an exemplary implementation mode, the base substrate 101 may be a flexible base substrate, or may be a rigid base substrate. The drive circuit layer 102 of each sub-pixel may include a pixel drive circuit composed of a plurality of transistors and a storage capacitor. The light emitting structure layer 103 of each sub-pixel may at least include an anode 301, a pixel definition layer 302, an organic emitting layer 303, and a cathode 304, wherein the anode 301 is connected with the pixel drive circuit, the organic emitting layer 303 is connected with the anode 301, the cathode 304 is connected with the organic emitting layer 303, and the organic emitting layer 303 emits light of a corresponding color under drive of the anode 301 and the cathode 304. The encapsulation structure layer 104 may include a first encapsulation layer 401, a second encapsulation layer 402, and a third encapsulation layer 403 that are stacked. The first encapsulation layer 401 and the third encapsulation layer 403 may be made of an inorganic material, the second encapsulation layer 402 may be made of an organic material, and the second encapsulation layer 402 is disposed between the first encapsulation layer 401 and the third encapsulation layer 403 to form a stacked structure of inorganic material/organic material/inorganic material, which ensures that external water vapor cannot enter the light emitting structure layer 103.

In an exemplary implementation mode, the organic emitting layer may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation mode, one or more layers of hole injection layers, hole transport layers, electron block layers, hole block layers, electron transport layers, and electron injection layers of all sub-pixels may be respectively connected together to be a common layer. Emitting layers of adjacent sub-pixels may be overlapped slightly, or may be mutually isolated.

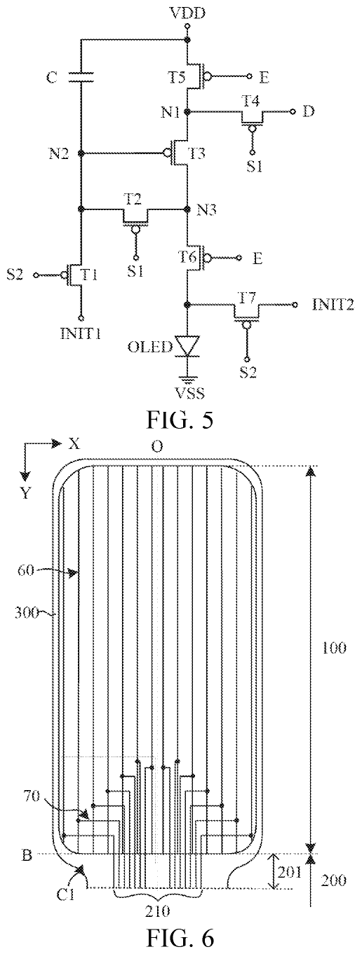

FIG. 5 is a schematic diagram of an equivalent circuit of a pixel drive circuit. In an exemplary implementation mode, the pixel drive circuit may have a structure of 3T1C, 4T1C, 5T1C, 5T2C, 6T1C, 7T1C, or 8T1C. FIG. 5 is a schematic diagram of an equivalent circuit of a pixel drive circuit. As shown in FIG. 5, the pixel drive circuit may include seven transistors (a first transistor T1 to a seventh transistor T7), one storage capacitor C, and the pixel drive circuit is respectively connected with eight signal lines (a data signal line D, a first scan signal line S1, a second scan signal line S2, a light emitting signal line E, a first initial signal line INIT1, a second initial signal line INIT2, a first power supply line VDD, and a second power supply line VSS).

In an exemplary implementation mode, the pixel drive circuit may include a first node N1, a second node N2, and a third node N3. The first node N1 is connected with a first electrode of the third transistor T3, a second electrode of the fourth transistor T4, and a second electrode of the fifth transistor T5 respectively. The second node N2 is connected with a second electrode of the first transistor, a first electrode of the second transistor T2, a control electrode of the third transistor T3, and a second end of the storage capacitor C respectively. The third node N3 is connected with a second electrode of the second transistor T2, a second electrode of the third transistor T3, and a first electrode of the sixth transistor T6 respectively.

In an exemplary implementation mode, a first end of the storage capacitor C is connected with the first power supply line VDD, and the second end of the storage capacitor C is connected with the second node N2, i.e., the second end of the storage capacitor C is connected with the control electrode of the third transistor T3.

A control electrode of the first transistor T1 is connected with the second scan signal line S2, a first electrode of the first transistor T1 is connected with the first initial signal line INIT1, and a second electrode of the first transistor is connected with the second node N2. When a scan signal with an on level is applied to the second scan signal line S2, the first transistor T1 transmits a first initial voltage to the control electrode of the third transistor T3 so as to initialize a charge amount of the control electrode of the third transistor T3.

A control electrode of the second transistor T2 is connected with the first scan signal line S1, a first electrode of the second transistor T2 is connected with the second node N2, and a second electrode of the second transistor T2 is connected with the third node N3. When a scan signal with an on level is applied to the first scan signal line S1, the second transistor T2 enables the control electrode of the third transistor T3 to be connected with the second electrode of the third transistor T3.

A control electrode of the third transistor T3 is connected with the second node N2, i.e., the control electrode of the third transistor T3 is connected with the second end of the storage capacitor C, a first electrode of the third transistor T3 is connected with the first node N1, and the second electrode of the third transistor T3 is connected with the third node N3. The third transistor T3 may be referred to as a drive transistor, and the third transistor T3 determines an amount of a drive current flowing between the first power supply line VDD and the second power supply line VSS according to a potential difference between the control electrode and the first electrode of the third transistor T3.

A control electrode of the fourth transistor T4 is connected with the first scan signal line S1, a first electrode of the fourth transistor T4 is connected with the data signal line D, and a second electrode of the fourth transistor T4 is connected with the first node N1. The fourth transistor T4 may be referred to as a switching transistor, a scan transistor, etc., and the fourth transistor T4 enables a data voltage of the data signal line D to be input into the pixel drive circuit when a scan signal with an on level is applied to the first scan signal line S1.

A control electrode of the fifth transistor T5 is connected with the light emitting signal line E, a first electrode of the fifth transistor T5 is connected with the first power supply line VDD, and a second electrode of the fifth transistor T5 is connected with the first node N1. A control electrode of the sixth transistor T6 is connected with the light emitting signal line E, a first electrode of the sixth transistor T6 is connected with the third node N3, and a second electrode of the sixth transistor T6 is connected with a first electrode of a light emitting device. The fifth transistor T5 and the sixth transistor T6 may be referred to as light emitting transistors. When a light emitting signal with an on level is applied to the light emitting signal line E, the fifth transistor T5 and the sixth transistor T6 enable the light emitting device to emit light by forming a drive current path between the first power supply line VDD and the second power supply line VSS.

A control electrode of the seventh transistor T7 is connected with the second scan signal line S2, a first electrode of the seventh transistor T7 is connected with the second initial signal line INIT2, and a second electrode of the seventh transistor T7 is connected with the first electrode of the light emitting device. When a scan signal with an on level is applied to the second scan signal line S2, the seventh transistor T7 transmits a second initialization voltage to the first electrode of the light emitting device so as to initialize a charge amount accumulated in the first electrode of the light emitting device or release a charge amount accumulated in the first electrode of the light emitting device.

In an exemplary implementation mode, the light emitting device may be an OLED including a first electrode (anode), an organic emitting layer, and a second electrode (cathode) which are stacked, or may be a QLED including a first electrode (anode), a quantum dot emitting layer, and a second electrode (cathode) which are stacked.

In an exemplary implementation mode, a second electrode of the light emitting device is connected with the second power supply line VSS, a signal of the second power supply line VSS is a continuously supplied low-level signal, and a signal of the first power supply line VDD is a continuously supplied high-level signal.

In an exemplary implementation mode, the first transistor T1 to the seventh transistor T7 may be P-type transistors, or may be N-type transistors. Use of a same type of transistors in a pixel drive circuit may simplify a process flow, reduce a process difficulty of a display panel, and improve a product yield. In some possible implementation modes, the first transistor T1 to the seventh transistor T7 may include a P-type transistor and an N-type transistor.

In an exemplary implementation mode, for the first transistor T1 to the seventh transistor T7, low temperature poly silicon thin film transistors may be used, or oxide thin film transistors may be used, or both a low temperature poly silicon thin film transistor and an oxide thin film transistor may be used. An active layer of a low temperature poly silicon thin film transistor may be made of Low Temperature Poly silicon (LTPS for short), and an active layer of an oxide thin film transistor may be made of an oxide semiconductor (Oxide). The low temperature poly silicon thin film transistor has advantages, such as a high mobility and fast charging, and the oxide thin film transistor has advantages, such a low drain current. The low temperature poly silicon thin film transistor and the oxide thin film transistor are integrated on one display substrate, that is a LTPS+Oxide (LTPO for short) display substrate, so that advantages of the low temperature poly silicon thin film transistor and the oxide thin film transistor may be utilized, low-frequency drive may be achieved, power consumption may be reduced, and display quality may be improved.

In an exemplary implementation mode, taking a case that the first transistor T1 to the seventh transistor T7 are all P-type transistors as an example, a working process of the pixel drive circuit may include following stages.

In a first stage A1, referred to as a reset stage, a signal of the second scan signal line S2 is a low-level signal, and signals of the first scan signal line S1 and the light emitting signal line E are high-level signals. The signal of the second scan signal line S2 is a low-level signal, which enables the first transistor T1 and the seventh transistor T7 to be turned on. The first transistor T1 is turned on so that a first initial voltage of the first initial signal line INIT1 is provided to the second node N2 to initialize the storage capacitor C to clear an original data voltage in the storage capacitor. The seventh transistor T7 is turned on, so that a second initial voltage of the second initial signal line INIT2 is provided to a first electrode of an OLED to initialize (reset) the first electrode of the OLED and clear its internal pre-stored voltage, thereby completing initialization and ensuring that the OLED does not emit light. The signals of the first scan signal line S1 and the light emitting signal line E are high-level signals, so that the second transistor T2, the fourth transistor T4, the fifth transistor T5, the sixth transistor T6, and the seventh transistor T7 are turned off.

In a second stage A2, referred to as a data writing stage or a threshold compensation stage, a signal of the first scan signal line S1 is a low-level signal, signals of the second scan signal line S2 and the light emitting signal line E are high-level signals, and the data signal line D outputs a data voltage. In this stage, the second end of the storage capacitor C is at a low level, so the third transistor T3 is turned on. The signal of the first scan signal line S1 is the low-level signal, so that the second transistor T2 and the fourth transistor T4 are turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd−|Vth|, wherein Vd is the data voltage output by the data signal line D, and Vth is the threshold voltage of the third transistor T3. A signal of the second scan signal line S2 is a high-level signal, so that the first transistor T1 is turned off. A signal of the light emitting signal line E is a high-level signal, so that the fifth transistor T5 and the sixth transistor T6 are turned off.

In a third stage A3, referred to as a light emitting stage, a signal of the light emitting signal line E is a low-level signal, and signals of the first scan signal line S1 and the second scan signal line S2 are high-level signals. The signal of the light emitting signal line E is the low-level signal, so that the fifth transistor T5 and the sixth transistor T6 are turned on, and a power voltage output by the first power supply line VDD provides a drive voltage to the first electrode of the OLED through the turned-on fifth transistor T5, the third transistor T3, and the sixth transistor T6 to drive the OLED to emit light.

In a drive process of the pixel drive circuit, a drive current flowing through the third transistor T3 (drive transistor) is determined by a voltage difference between a gate electrode and the first electrode of the third transistor T3. The voltage of the second node N2 is Vdata−|Vth|, so the drive current of the third transistor T3 is as follows.

$$I = K * {( Vgs - Vth )}^{2} = K * {[ ( Vdd - Vd + \vert Vth \vert ) - Vth ]}^{2} = K * {[ Vdd - Vd ]}^{2}$$

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

With development of OLED display technologies, consumers have higher requirements for a display effect of a display product. An extremely narrow border has become a new trend in development of display products. Therefore, border narrowing or even a borderless design has attracted more and more attention in a design of an OLED display product. In a display substrate, a bonding region generally includes a fanout region, a bending region, a drive chip region, and a bonding pin region sequentially disposed along a direction away from a display region. Since a width of the bonding region is smaller than a width of the display region, signal lines of an integrated circuit and a bonding pad in the bonding region need to be led to a relatively wide display region through the fanout region in a fanout trace manner, the greater a width difference between the display region and the bonding region is, the more oblique fanout lines in a fan-shaped region is, the longer a distance between the drive chip region and the display region is, so the fan-shaped region occupies relatively large space, which causes a relatively large difficulty in a narrowing design of a lower bezel, the lower bezel being always maintained at about 2.0 mm. In another display substrate, a bonding region and a bezel region are usually provided with power supply leads, and the power supply leads are configured to transmit low-voltage power supply signals. In order to reduce voltage drop of the low-voltage power supply signals, a width of a power supply lead is large, resulting in a wider bezel of a display apparatus.

An exemplary embodiment of the present disclosure provides a display substrate, and a structure in which a data connection line is located in a display region (Fanout in AA, abbreviated as FIAA) is adopted. Ends of a plurality of data connection lines are correspondingly connected with a plurality of data signal lines in the display region, the other ends of the plurality of data connection lines extend to a bonding region and are correspondingly connected with an integrated circuit in the bonding region. Since the bonding region does not need to be provided with a fan-shaped oblique line, a width of a fanout region is reduced, and a width of a lower bezel is effectively reduced.

An exemplary embodiment of the present disclosure provides a display substrate including a display region, the display region includes a drive circuit layer disposed on a base substrate and a light emitting structure layer disposed at a side of the drive circuit layer away from the base substrate, the drive circuit layer includes a plurality of circuit units, a plurality of data signal lines, a plurality of data connection lines, a plurality of low-voltage power supply lines and a plurality of power supply traces, the light emitting structure layer includes a plurality of light emitting devices, the circuit units include pixel drive circuits, the data signal lines are configured to provide data signals to the pixel drive circuits, the low-voltage power supply lines are configured to continuously provide low power supply voltage signals to the light emitting devices; the data connection lines are connected with the data signal lines, and the power supply traces are connected with the low-voltage power supply lines.

In an exemplary implementation mode, a data connection line includes a first connection line extending along a first direction and a second connection line extending along a second direction, a power supply trace includes a first power supply trace extending along the first direction and a second power supply trace extending along the second direction, the first connection line is connected with the second connection line, the first power supply trace is connected with the second power supply trace, and the first direction and the second direction intersect.

In an exemplary implementation mode, on a plane parallel to the base substrate, the display region at least includes a first region provided with the first connection line, and at least one circuit unit of the first region includes the first connection line, the first power supply trace, and the second power supply trace, the first connection line is connected with a data signal line, and the second power supply trace is connected with a low-voltage power supply line.

In an exemplary implementation mode, on a plane parallel to the base substrate, the display region further includes a second region provided with the second connection line, the second connection line is included in at least one circuit unit of the second region, and second connection lines in circuit units adjacent in the second direction are connected with each other.

In an exemplary implementation mode, on a plane parallel to the base substrate, the display region further includes a third region that is not overlapped with orthographic projections of the first connection line and the second connection line on the base substrate, and at least one circuit unit of the third region includes the first power supply trace and the second power supply trace, the second power supply trace is connected with the low-voltage power supply line through a second connection hole.

In the present disclosure, “A extends along a B direction” means that A may include a main portion and a secondary portion connected with the main portion, the main portion is a line, a line segment, or a strip-shaped body, the main portion extends along the B direction, and a length of the main portion extending along the B direction is greater than a length of the secondary portion extending along another direction. In following description, “A extends along a B direction” means “a main body portion of A extends along a B direction”. In an exemplary implementation mode, a second direction Y may be a direction pointing to a bonding region from a display region, and an opposite direction of the second direction Y may be a direction pointing to the display region from the bonding region.

FIG. 6 is a schematic diagram of a planar structure of a display substrate according to an exemplary embodiment of the present disclosure. On a plane perpendicular to the display substrate, the display substrate may include a drive circuit layer disposed on the base substrate, a light emitting structure layer disposed at a side of the drive circuit layer away from the base substrate, and an encapsulation structure layer disposed at a side of the light emitting structure layer away from the base substrate. As shown in FIG. 6, on a plane parallel to the display substrate, the display substrate may at least include a display region 100, a bonding region 200 located on a side of the display region 100 in the second direction Y, and a bezel region 300 located on another side of the display region 100. In an exemplary implementation mode, the drive circuit layer of the display region 100 may include a plurality of circuit units constituting a plurality of unit rows and a plurality of unit columns, at least one circuit unit may include a pixel drive circuit, and the pixel drive circuit is configured to output a corresponding current to a connected light emitting device. The light emitting structure layer of the display region 100 may include multiple sub-pixels constituting a pixel array, wherein at least one sub-pixel may include a light emitting device, the light emitting device is connected with a pixel drive circuit of a corresponding circuit unit, and the light emitting device is configured to emit light with corresponding brightness in response to a current outputted by the connected pixel drive circuit.

In an exemplary implementation mode, the drive circuit layer of the display region 100 may further include a plurality of data signal lines 60 and a plurality of data connection lines 70, at least one data signal line 60 is connected with a plurality of pixel drive circuits in a unit column, the data signal line 60 is configured to provide a data signal to the connected pixel drive circuits, at least one data connection line 70 is correspondingly connected with the data signal line 60, and the data connection line 70 is configured such that the data signal line 60 is correspondingly connected with a leading out line 210 in the bonding region 200 through the data connection line 70.

In an exemplary implementation mode, a sub-pixel mentioned in the present disclosure refers to a region divided according to a light emitting device, and a circuit unit mentioned in the present disclosure refers to a region divided according to a pixel drive circuit. In an exemplary implementation mode, a position of an orthographic projection of the sub-pixel on the base substrate may correspond to a position of an orthographic projection of the circuit unit on the base substrate, or a position of an orthographic projection of the sub-pixel on the base substrate may not correspond to a position of an orthographic projection of the circuit unit on the base substrate.

In an exemplary implementation mode, a plurality of circuit units sequentially disposed along a first direction X may be referred to as a unit row, and a plurality of circuit units sequentially disposed along the second direction Y may be referred to as a unit column. A plurality of unit rows and a plurality of unit columns constitute a circuit unit array arranged in an array, and the first direction X and the second direction Y intersect. In an exemplary implementation mode, the second direction Y may be an extension direction (vertical direction) of a data signal line, and the first direction X may be perpendicular to the second direction Y (horizontal direction).

In an exemplary implementation mode, the bonding region 200 may include at least a lead region 201, a bending region, and a drive chip region which are sequentially disposed along a direction away from the display region, the lead region 201 is connected to the display region 100, the bending region is connected to the lead region 201, and the drive chip region is connected to the bending region. The lead region 201 may be provided with a plurality of leading out lines 210, the plurality of leading out lines 210 may extend along the second direction Y, first ends of the plurality of leading out lines 210 are connected with an integrated circuit of a composite circuit region, and second ends of the plurality of leading out lines 210 cross the bending region to extend to the lead region 201 and then are correspondingly connected with a data connection line 70, so that the integrated circuit applies a data signal to the data signal line through a leading out line and a data connection line. Since the data connection line is disposed in the display region, a length of the lead region in the second direction Y may be effectively reduced, a width of a lower bezel is greatly shortened, and a screen-to-body ratio is increased, which is beneficial to achieve full-screen display.

In an exemplary implementation mode, a plurality of data signal lines disposed in the display region 100 may have a shape of a line extending along the second direction Y, a plurality of data connection lines 70 disposed in the display region 100 may have a shape of a broken line, a data connection line 70 may include a first connection line extending along the first direction X and a second connection line extending along the second direction Y, first ends of a plurality of first connection lines (first ends of the data connection lines 70) are correspondingly connected with the plurality of data signal lines 60 through connection holes, second ends of the plurality of first connection lines, after extending along the first direction X or an opposite direction of the first direction X, are connected with first ends of the second connection lines, and second ends of a plurality of second connection lines (second ends of the plurality of data connection lines 70) extend toward a direction of the bonding region 200 and cross a boundary B of the display region, and are correspondingly connected with the plurality of leading out lines 210 of the lead region 201. In an exemplary implementation mode, the boundary B of the display region may be a junction of the display region 100 and the bonding region 200.

In an exemplary implementation mode, a data connection line 70 and a leading out line 210 may be connected directly or may be connected through a via, which is not limited here in the present disclosure.

In an exemplary implementation mode, multiple second connection lines may be disposed parallel to a data signal line 60, and multiple first connection lines may be disposed perpendicular to the data signal line 60.

In an exemplary implementation mode, pitches between adjacent second connection lines in the first direction X may be substantially the same, and pitches between adjacent first connection lines in the second direction Y may be substantially the same, which is not limited here in the present disclosure.

In an exemplary implementation mode, the display region 100 may have a center line O, wherein a plurality of data signal lines 60 and a plurality of data connection lines 70 in the display region 100, and a plurality of leading out lines 210 in the lead region 201 may be symmetrically disposed with respect to the center line O, and the center line O may be a straight line bisecting a plurality of unit columns of the display region 100 and extending along the second direction Y.

FIG. 7 is a schematic diagram of an arrangement of data connection lines according to an exemplary embodiment of the present disclosure, and is an enlarged view of a C1 region in FIG. 6, which illustrates a structure of 7 data signal lines, 7 data connection lines, and 7 leading out lines. As shown in FIG. 7, In an exemplary implementation mode, a plurality of data signal lines of the display region 100 may include a first data signal line 60-1 to a seventh data signal line 60-7, a plurality of data connection lines of the display region 100 may include a first data connection line 70-1 to a seventh data connection line 70-7, and a plurality of leading out lines of the lead region 201 may include a first leading out line 210-1 to a seventh leading out line 210-7.

In an exemplary implementation mode, the first data signal line 60-1 to the seventh data signal line 60-7, the first data connection line 70-1 to the seventh data connection line 70-7, and the first leading out line 210-1 to the seventh leading out line 210-7 may all be disposed sequentially along the first direction X. A first end of an i-th data connection line 70-i is connected with an i-th data signal line 60-i through a connection hole in the display region 100, and a second end of the i-th data connection line 70-i, after extending to the lead region 201, is connected with an i-th leading out line 210-i, i=1 to 7.

In an exemplary implementation mode, distances between a plurality of connection holes through which data connection lines 70 and data signal lines 60 are connected correspondingly and an edge B of the display region may be different. For example, a distance between a connection hole connecting the first data connection line 70-1 and the first data signal line 60-1, and the edge B of the display region may be smaller than a distance between a connection hole connecting the second data connection line 70-2 and the second data signal line 60-2, and the edge B of the display region. For another example, the distance between the connection hole connecting the second data connection line 70-2 and the second data signal line 60-2, and the edge B of the display region may be greater than a distance between a connection hole connecting the third data connection line 70-3 and the third data signal line 60-3, and the edge B of the display region.

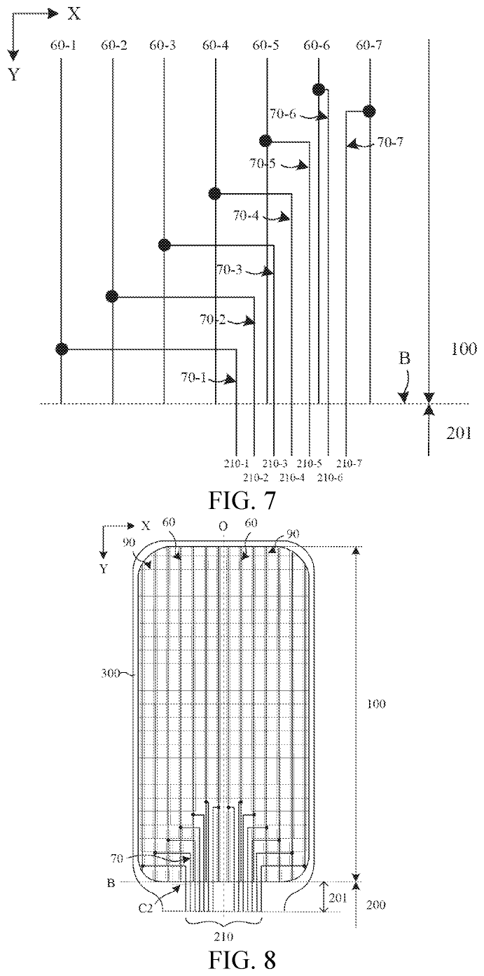

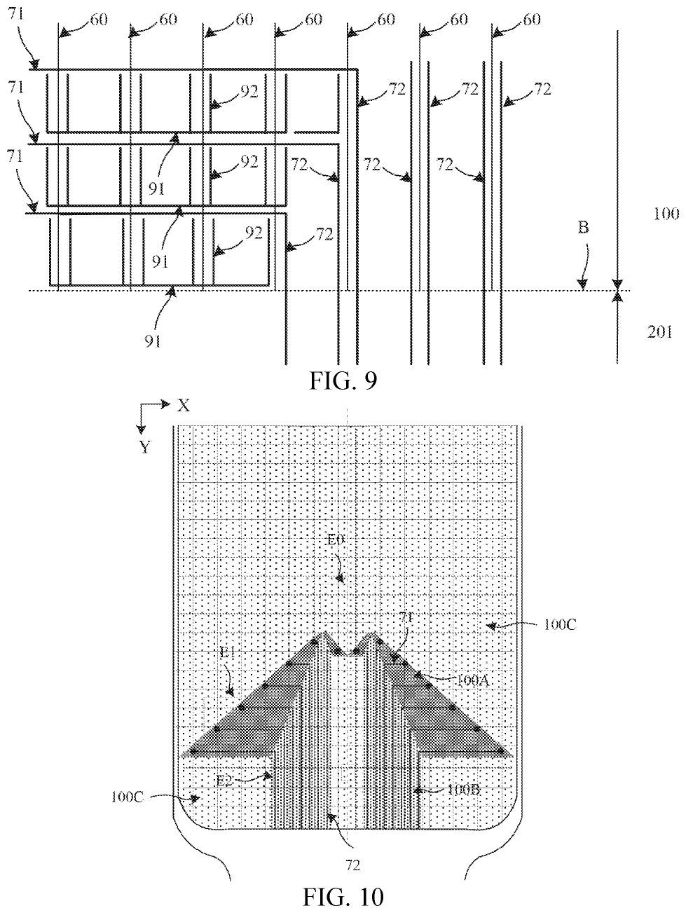

FIG. 8 is a schematic diagram of a planar structure of another display substrate according to an exemplary embodiment of the present disclosure, and FIG. 9 is an enlarged view of a C2 region in FIG. 8. The drive circuit layer of the display region 100 may include a plurality of circuit units constituting a circuit unit array, a plurality of data signal lines 60, a plurality of data connection lines 70, and a power supply trace 90 with a mesh communication structure. Layouts and structures of the plurality of circuit units, the plurality of data signal lines 60, and the plurality of data connection lines 70 are substantially the same as those shown in FIG. 6 above.

In an exemplary implementation mode, a data connection line 70 may include a first connection line 71 extending along the first direction X and a second connection line 72 extending along the second direction Y, the first connection line 71 and the second connection line 72 constitute the data connection line 70 in a shape of a broken line. The first connection line 71 and the second connection line 72 may be disposed in a same conductive layer, and the first connection line 71 and the data signal line 60 may be disposed in different conductive layers. A first end of the first connection line 71 is connected with the data signal line 60 through a first connection hole. A second end of the first connection line 71, after extending along the first direction X or an opposite direction of the first direction X, is directly connected with a first end of the second connection line 72. A second end of the second connection line 72, after extending toward a direction of the lead region 201 along the second direction Y, is connected with a leading out line 210.

In an exemplary implementation mode, a power supply trace 90 may include a plurality of first power supply traces 91 extending along the first direction X and a plurality of second power supply traces 92 extending along the second direction Y, the plurality of first power supply traces 91 may be sequentially disposed along the second direction Y, the plurality of second power supply traces 92 may be sequentially disposed along the first direction X, the first power supply traces 91 and the second power supply traces 92 are connected with each other to form the power supply trace 90 with a mesh communication structure, the power supply trace 90 is configured to be connected with a low-voltage power supply line in the drive circuit layer and the low-voltage power supply line is configured to continuously provide a low power supply voltage signal to a plurality of light emitting devices in the light emitting structure layer.

In an exemplary implementation mode, the first power supply traces 91 and the second power supply traces 92 may be disposed in a same conductive layer, the first power supply traces 91 and the low-voltage power supply line may be disposed in different conductive layers, and the second power supply traces may be connected with the low-voltage power supply line through a second connection hole, achieving a connection between the power supply trace 90 with the mesh communication structure and the low-voltage power supply line.

FIG. 10 is a schematic diagram of partition of a display region according to an exemplary embodiment of the present disclosure. As shown in FIG. 10, since data connection lines are disposed in some regions in the display region, and a data connection line includes a first connection line extending along the first direction X and a second connection line extending along the second direction Y, the display region may be divided into a first region 100A, a second region 100B, and a third region 100C according to presence or absence of a data connection line and an extension direction of a data connection line. The first region 100A may be a region where the first connection line 71 is disposed (a fanout line lateral trace region), the second region 100B may be a region where the second connection line 72 is disposed (a fanout line longitudinal trace region), and the third region 100C may be a region in which orthographic projections of the first connection line 71 and the second connection line 72 on the base substrate are not overlapped (a normal region), that is, the third region 100C may be a region where the first connection line 71 and the second connection line 72 are not disposed.

In an exemplary implementation mode, the first region 100A may include multiple circuit units, wherein an orthographic projection of the first connection line 71 on a plane of a display substrate is at least partially overlapped with orthographic projections of pixel drive circuits in multiple circuit units of the first region 100A on the plane of the display substrate, and the orthographic projections of the pixel drive circuits in the multiple circuit units of the first region 100A on the plane of the display substrate are not overlapped with an orthographic projection of the second connection line 72 on the plane of the display substrate.

In an exemplary implementation mode, the second region 100B may include multiple circuit units, wherein the orthographic projection of the second connection line 72 on the plane of the display substrate is at least partially overlapped with orthographic projections of pixel drive circuits in the multiple circuit units of the second region 100B on the plane of the display substrate, and the orthographic projections of the pixel drive circuits in the multiple circuit units of the second region 100B on the plane of the display substrate are not overlapped with the orthographic projection of the first connection line 71 on the plane of the display substrate.

In an exemplary implementation mode, the third region 100C may include multiple circuit units, wherein orthographic projections of pixel drive circuits in the multiple circuit units of the third region 100C on the plane of the display substrate are not overlapped with orthographic projections of the first connection line 71 and the second connection line 72 on the plane of the display substrate.

In an exemplary implementation mode, division of various regions shown in FIG. 10 is only exemplary illustration. Since the first region 100A, the second region 100B, and the third region 100C are divided according to whether there is a data connection line or not and by taking an extension direction of a data connection line as a division basis, shapes of the three regions may be regular polygons or irregular polygons, and the display region may be divided into one or more first regions 100A, one or more second regions 100B, and one or more third regions 100C, which are not limited here in the present disclosure.

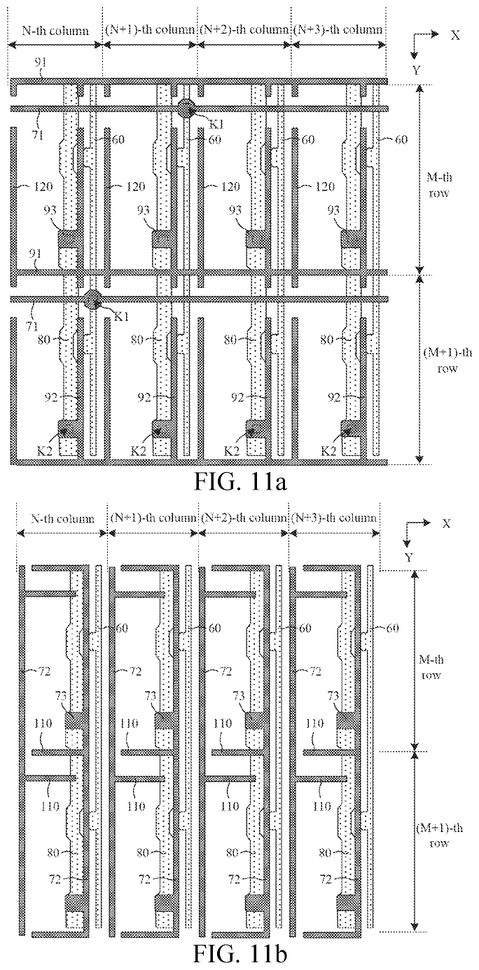

FIG. 11a is a schematic diagram of a structure of a first region according to an exemplary embodiment of the present disclosure, and the first region may include a plurality of circuit units. As shown in FIG. 11a, at least one circuit unit in the first region may include a data signal line 60, a first connection line 71, a second power supply line 80, a first power supply trace 91, a second power supply trace 92, a power supply connection electrode 93, and a second compensation line 120. The first connection line 71 and the first power supply trace 91 may have a shape of a straight line with a main body portion extending along the first direction X, and the data signal line 60, the second power supply line 80, the second power supply trace 92, and the second compensation line 120 may have a shape of a straight line with a main body portion extending along the second direction Y. The second power supply line 80, as a low-voltage power supply line of the present disclosure, is configured to continuously provide a low power supply voltage signal (VSS), and the data signal line 60 is configured to provide a data signal.

In an exemplary implementation mode, in at least one circuit unit of the first region, the data signal line 60 and the second power supply trace 92 may be disposed at a side of the second power supply line 80 in the first direction X, and the second power supply trace 92 may be disposed between the second power supply line 80 and the data signal line 60, the second compensation line 120 may be disposed at a side of the second power supply line 80 away from the data signal line 60, the first power supply trace 91 may be disposed at a side of the circuit unit in the second direction Y, and the first connection line 71 may be disposed at a side of the circuit unit in an opposite direction of the second direction Y.

In an exemplary implementation mode, the first connection line 71 and the second connection line 72 may be disposed in a same conductive layer, and the first connection line 71 and the data signal line 60 may be disposed in different conductive layers.

In an exemplary implementation mode, in at least one circuit unit of the first region, the first connection line 71 extending along the first direction X is connected with the data signal line 60 extending along the second direction Y through a first connection hole K1, thereby achieving a connection between the first connection line 71 and the data signal line 60.

In an exemplary implementation mode, in the first region, the first connection line 71 may be continuously disposed in a plurality of circuit units in one unit row, and first connection lines 71 in circuit units adjacent in the first direction X are connected with each other.

In an exemplary implementation mode, the first power supply trace 91 and the second power supply trace 92 may be disposed in a same conductive layer, and the second power supply trace 92 and the second power supply trace 80 may be disposed in different conductive layers.

In an exemplary implementation mode, in at least one circuit unit of the first region, the second power supply trace 92 extending along the second direction Y is connected with the second power supply line 80 extending along the second direction Y through a second connection hole K2, thereby achieving a connection between the second power supply trace 92 and the second power supply line 80.

In an exemplary implementation mode, in at least one unit row of the first region, the first power supply trace 91 extending along the first direction X is directly connected with a plurality of second power supply traces 92 extending along the second direction Y to constitute a power supply trace with a mesh communication structure.

In an exemplary implementation mode, at least one circuit unit of the first region may also include a power supply connection electrode 93, the power supply connection electrode 93 may have a rectangular shape, the power supply connection electrode 93 may be disposed at a side of the second power supply trace 92 away from the data signal line 60 and connected with the second power supply trace 92, an orthographic projection of the power supply connection electrode 93 on the base substrate is at least partially overlapped with an orthographic projection of the second power supply line 80 on the base substrate, and the power supply connection electrode 93 is connected with the second power supply line 80 through a second connection hole K2, thereby achieving a connection between a grid-like power supply lead and the second power supply line 80.

In an exemplary implementation mode, in the first region, the first power supply trace 91 may be continuously disposed in a plurality of circuit units in one unit row, and first power supply traces 91 in circuit units adjacent in the first direction X are connected with each other.

In an exemplary implementation mode, in the first region, second power supply traces 92 may be disposed at intervals among a plurality of circuit units in one unit column, i.e., the second power supply traces 92 in circuit units adjacent in the second direction Y are disposed at intervals, so that a first connection line 71 is disposed between second power supply traces 92 adjacent in the second direction Y, and an orthographic projection of the first connection line 71 on the base substrate is not overlapped with orthographic projections of the second power supply traces 92 on the base substrate.

In an exemplary implementation mode, in the first region, the first power supply trace 91 extending along the first direction X is directly connected with a plurality of second compensation lines 120 extending along the second direction Y.

In an exemplary implementation mode, in the first region, the second compensation lines 120 may be disposed at intervals among a plurality of circuit units in one unit column, i.e., the second compensation lines 120 are disposed at intervals in circuit units adjacent in the second direction Y, so that a first connection line 71 is disposed between the second compensation lines 120 adjacent in the second direction Y, and an orthographic projection of the first connection line 71 on the base substrate is not overlapped with orthographic projections of the second compensation lines 120 on the base substrate.

FIG. 11b is a schematic diagram of a structure of a second region according to an exemplary embodiment of the present disclosure, and the second region may include a plurality of circuit units. As shown in FIG. 11b, at least one circuit unit in the second region may include a data signal line 60, a second connection line 72, a second power supply line 80, and a first compensation line 110. The first compensation line 110 may have a shape of a straight line with a main body portion extending along the first direction X, and the data signal line 60, the second connection line 72, and the second power supply line 80 may have a shape of a straight line with a main body portion extending along the second direction Y. A first end of the second connection line 72 is connected with a leading out line located in the lead region, and a second end of the second connection line 72 is connected with a first connection line 71 located in the display region, so that the first connection line 71 and the second connection line 72 connected with each other constitute a data connection line in a shape of a broken line.

In an exemplary implementation mode, two second connection lines 72 may be disposed in at least one circuit unit of the second region. The two second connection lines 72 may include a first side connection line and a second side connection line, the first side connection line may be disposed between the second power supply line 80 and the data signal line 60, and the second side connection line may be disposed at a side of the second power supply line 80 away from the data signal line 60.

In an exemplary implementation mode, at least two first compensation lines 110 may be disposed in at least one circuit unit of the second region. The at least two first compensation lines 110 may include at least one first side compensation line and at least one second side compensation line, a first end of the first side compensation line is connected with the first side connection line, a second end of the first side compensation line extends toward a direction close to the second side connection line, a first end of the second side compensation line is connected with the second side connection line, and a second end of the second side compensation line extends toward a direction close to the first side connection line, so that the two first compensation lines 110 in the circuit unit form an interdigital structure.

In an exemplary implementation mode, at least one circuit unit of the second region may also include a dummy connection electrodes 73, the dummy connection electrodes 73 may have a rectangular shape, the dummy connection electrode 73 may be disposed at a side of the second connection line 72 away from the data signal line 60 and connected with the second connection line 72, and an orthographic projection of the dummy connection electrode 73 on the base substrate is at least partially overlapped with an orthographic projection of the second power supply line 80 on the base substrate.

In an exemplary implementation mode, in the second region, the second connection line 72 may be continuously disposed in a plurality of circuit units in one unit column, and second connection lines 72 in circuit units adjacent in the second direction Y are connected with each other.

In an exemplary implementation mode, in the second region, the first compensation lines 110 may be disposed at intervals among a plurality of circuit units in one unit row.

FIG. 11c is a schematic diagram of a structure of a third region according to an exemplary embodiment of the present disclosure, and the third region may include a plurality of circuit units. As shown in FIG. 11c, at least one circuit unit in the third region may include a data signal line 60, a second power supply line 80, a first power supply trace 91, a second power supply trace 92, a power supply connection electrode 93, a first compensation line 110, and a second compensation line 120. The first power supply trace 91 and the first compensation line 110 may have a shape of a straight line with a main body portion extending along the first direction X, and the data signal line 60, the second power supply line 80, the second power supply trace 92, and the second compensation line 120 may have a shape of a straight line with a main body portion extending along the second direction Y.

In an exemplary implementation mode, in at least one circuit unit of the third region, the data signal line 60 may be disposed at a side of the second power supply line 80 in the first direction X, the second power supply trace 92 may be disposed between the second power supply line 80 and the data signal line 60, the second compensation line 120 may be disposed at a side of the second power supply line 80 away from the data signal line 60, the first power supply trace 91 may be disposed at a side of the circuit unit in the second direction Y, and the first compensation line 110 may be disposed at a side of the circuit unit in an opposite direction of the second direction Y.

In an exemplary implementation mode, in at least one circuit unit of the third region, the second power supply trace 92 extending along the second direction Y is connected with the second power supply line 80 extending along the second direction Y through a second connection hole K2, achieving a connection between the second power supply trace 92 and the second power supply line 80.

In an exemplary implementation mode, the first power supply trace 91 and the second power supply trace 92 may be disposed in a same conductive layer, and in at least one unit row of the third region, the first power supply trace 91 extending along the first direction X is directly connected with a plurality of second power supply traces 92 extending along the second direction Y to constitute a power supply trace with a mesh communication structure.

In an exemplary implementation mode, in the third region, the first power supply trace 91 may be continuously disposed in a plurality of circuit units in one unit row, and first power supply traces 91 in circuit units adjacent in the first direction X are connected with each other.

In an exemplary implementation mode, in the first region, the second power supply trace 92 may be continuously disposed in a plurality of circuit units in one unit column, and second power supply traces 92 in circuit units adjacent in the second direction Y are connected with each other.

In an exemplary implementation mode, at least one circuit unit of the third region may also include a power supply connection electrode 93, the power supply connection electrode 93 may have a rectangular shape, the power supply connection electrode 93 may be disposed at a side of the second power supply trace 92 away from the data signal line 60 and connected with the second power supply trace 92, an orthographic projection of the power supply connection electrode 93 on the base substrate is at least partially overlapped with an orthographic projection of the second power supply line 80 on the base substrate, and the power supply connection electrode 93 is connected with the second power supply line 80 through a second connection hole K2, thereby achieving a connection between a grid-like power supply lead and the second power supply line 80.

In an exemplary implementation mode, in the third region, the first compensation line 110 may be continuously disposed in a plurality of circuit units in one unit row, and first compensation lines 110 in circuit units adjacent in the first direction X are connected with each other.

In an exemplary implementation mode, in the third region, the second compensation line 120 may be continuously disposed in a plurality of circuit units in one unit column, and second compensation lines 120 in circuit units adjacent in the second direction Y are connected with each other.

In an exemplary implementation mode, the first power supply trace 91, the second power supply trace 92, the first compensation line 110, and the second compensation line 120 may be disposed in a same conductive layer.

In an exemplary implementation mode, in at least one unit row of the third region, the first power supply trace 91 extending along the first direction X is directly connected with a plurality of second compensation lines 120 extending along the second direction Y.

In an exemplary implementation mode, in at least one unit row of the third region, the second power supply trace 92 extending along the second direction Y is directly connected with a plurality of first compensation lines 110 extending along the first direction X.

In an exemplary implementation mode, in at least one circuit unit of the third region, the first power supply trace 91 and the first compensation line 110 extending along the first direction X, and the second power supply trace 92 and the second compensation line 120 extending along the second direction Y are connected with each other to form a structure in a shape of a Chinese character “ [symbol] ”.

In an exemplary implementation mode, in at least one unit row including circuit units of the first region, circuit units of the second region, and circuit units of the third region, the first power supply trace 91 of the first region, the first side compensation line in the first compensation line 110 of the second region, and the first power supply trace 91 of the third region may be located on a same straight line extending along the first direction X, the first connection line 71 of the first region, the second side compensation line in the first compensation line 110 of the second region, and the first compensation line 110 of the third region may be located on a same straight line extending along the first direction X, and the power supply connection electrode 93 of the first region, the dummy connection electrode 73 of the second region, and the power supply connection electrode 93 of the third region may be located on a same straight line extending along the first direction X. In at least one unit column including circuit units of the first region, circuit units of the second region, and circuit units of the third region, the second power supply trace 92 of the first region, the first side connection line in the second connection line 72 of the second region, and the second power supply trace 92 of the third region may be located on a same straight line extending along the second direction Y, the second compensation line 120 of the first region, the second side connection line of the second connection line 72 in the second region, and the second compensation line 120 of the third region may be located on a same straight line extending along the second direction Y, and the power supply connection electrode 93 of the first region, the dummy connection electrode 73 of the second region, and the power supply connection electrode 93 of the third region may be located on a same straight line extending along the second direction. Therefore, traces of the first region, the second region, and the third region present substantially similar morphologies, which may not only improve uniformity of preparation processes, but also enable different regions to achieve basically a same display effect under transmitted light and reflected light, effectively avoiding poor appearance of the display substrate, and improving display attribute and display quality.

In an exemplary implementation mode, on a plane perpendicular to the display substrate, the drive circuit layer includes a semiconductor layer, a first conductive layer, a second conductive layer, a third conductive layer, a fourth conductive layer, and a fifth conductive layer that are sequentially disposed on the base substrate. The semiconductor layer includes at least active layers of a plurality of transistors, the first conductive layer includes at least gate electrodes of the plurality of transistors and a first electrode plate of a storage capacitor, the second conductive layer includes at least a second electrode plate of the storage capacitor, the third conductive layer includes at least first electrodes and second electrodes of the plurality of transistors, the fourth conductive layer includes at least a data signal line 60 and a second power supply line 80, and the fifth conductive layer includes at least a first connection line 71, a second connection line 72, a first power supply trace 91, and a second power supply trace 92, the first connection line 71 and the second connection line 72 are of an interconnected integral structure, the first connection line 71 is connected with the data signal line 60 through a first connection hole, the first power supply trace 91 and the second power supply trace 92 are of an interconnected integral structure, and the second power supply trace 92 is connected with the second power supply line 80 through a second connection hole.

In an exemplary implementation mode, the drive circuit layer may further include at least a first insulation layer disposed between the base substrate and the semiconductor layer, a second insulation layer disposed between the semiconductor layer and the first conductive layer, a third insulation layer disposed between the first conductive layer and the second conductive layer, a fourth insulation layer disposed between the second conductive layer and the third conductive layer, a first planarization layer disposed between the third conductive layer and the fourth conductive layer, a second planarization layer disposed between the fourth conductive layer and the fifth conductive layer, and a third planarization layer disposed at a side of the fifth conductive layer away from the base substrate.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or another process. If the “thin film” does not need to be processed through a patterning process in an entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary implementation mode, taking eight circuit units (2 unit rows and 4 unit columns) as an example, the preparation process of the display substrate may include following operations.

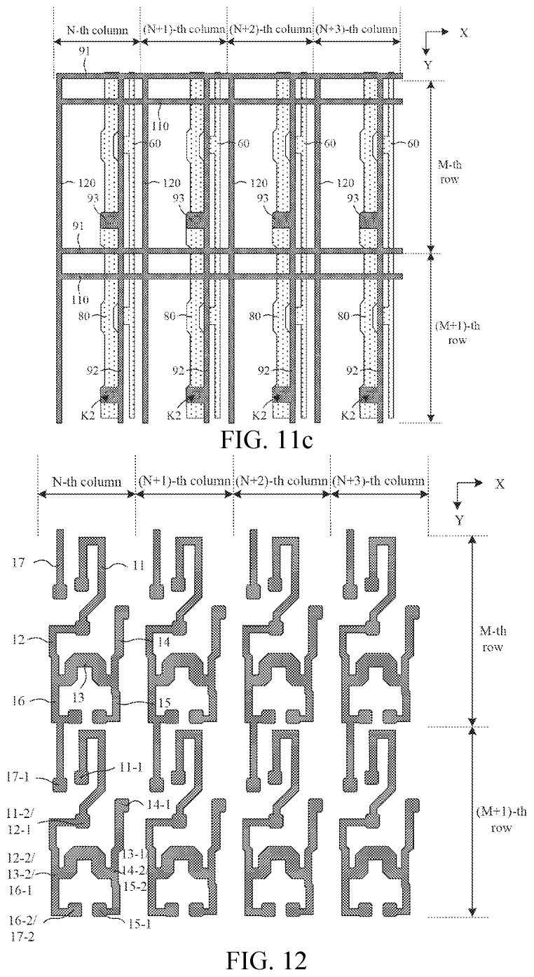

(1) A pattern of a semiconductor layer is formed. In an exemplary implementation mode, forming a pattern of a semiconductor layer may include: sequentially depositing a first insulation thin film and a semiconductor thin film on a base substrate, and patterning the semiconductor thin film through a patterning process to form a first insulation layer covering the base substrate and a semiconductor layer disposed on the first insulation layer, as shown in FIG. 12, and FIG. 12 is an enlarged view of an E0 region in FIG. 10.

In an exemplary implementation mode, the semiconductor layer of each circuit unit in the display region may include at least a first active layer 11 of the first transistor T1 to a seventh active layer 17 of the seventh transistor T7, the first active layer 11 to a sixth active layer 16 are of an interconnected integral structure, and the sixth active layer 16 and the seventh active layer 17 of adjacent circuit units in each unit column are of an interconnected integral structure. For example, the sixth active layer 16 of a circuit unit in an M-th row and the seventh active layer 17 of a circuit unit in an (M+1)-th row in each unit column are connected with each other.

In an exemplary implementation mode, the first active layer 11, the second active layer 12, the fourth active layer 14, and the seventh active layer 17 in the circuit unit in the M-th row may be located on a side of the third active layer 13 of a present circuit unit away from the circuit unit in the (M+1)-th row, the first active layer 11 and the seventh active layer 17 may be located on a side of the second active layer 12 and the fourth active layer 14 away from the third active layer 13, and the fifth active layer 15 and the sixth active layer 16 in the circuit unit in the M-th row may be located on a side of the third active layer 13 close to the circuit unit in the (M+1)-th row.

In an exemplary implementation mode, the first active layer 11 may be in an “n” shape, the second active layer 12, the fifth active layer 15, and the sixth active layer 16 may be in an “L” shape, the third active layer 13 may be in an “2” shape, the fourth active layer 14 and the seventh active layer 17 may be in an “I” shape.

In an exemplary implementation mode, an active layer of each transistor may include a first region, a second region, and a channel region located between the first region and the second region.

A first region 11-1 of the first active layer 11, a first region 14-1 of the fourth active layer 14, a first region 15-1 of the fifth active layer 15, and a first region 17-1 of the seventh active layer 17 may be individually disposed. A second region 11-2 of the first active layer 11 may serve as a first region 12-1 of the second active layer 12 (a second node N2); a first region 13-1 of the third active layer 13 may simultaneously serve as a second region 14-2 of the fourth active layer 14 and a second region 15-2 of the fifth active layer 15 (a first node N1); a second region 13-2 of the third active layer 13 may simultaneously serve as a second region 12-2 of the second active layer 12 and a first region 16-1 of the sixth active layer 16 (a third node N3); a second region 12-2 of the sixth active layer 16 may simultaneously serve as a second region 17-2 of the seventh active layer 17.

In an exemplary implementation mode, patterns of a semiconductor of an E1 region and an E2 region in FIG. 10 are substantially the same as a pattern of a semiconductor of the E0 region.

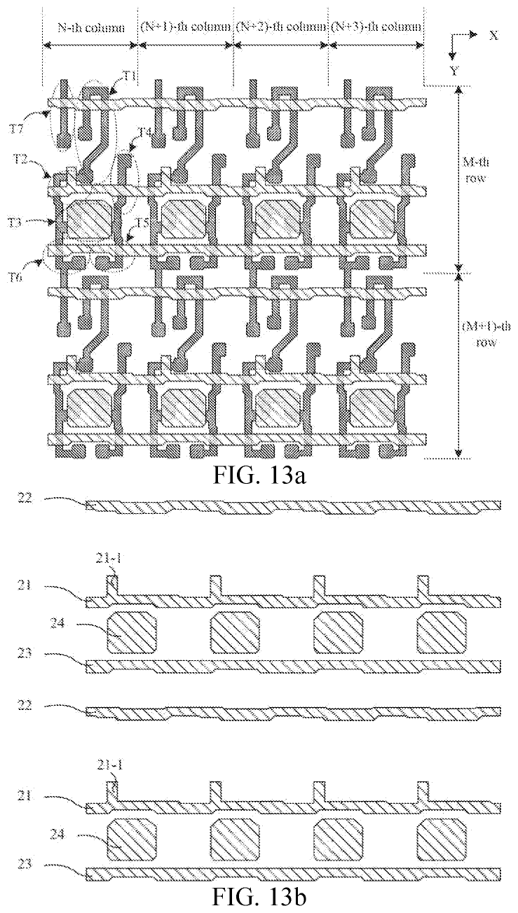

(2) A pattern of a first conductive layer is formed. In an exemplary implementation mode, forming a pattern of a first conductive layer may include: sequentially depositing a second insulation thin film and a first conductive thin film on the base substrate on which the above-mentioned pattern is formed, and patterning the first conductive thin film through a patterning process to form a second insulation layer that covers the pattern of the semiconductor layer and form a pattern of a first conductive layer disposed on the second insulation layer, as shown in FIG. 13a and FIG. 13b, wherein FIG. 13a is an enlarged view of the E0 region in FIG. 10, and FIG. 13b is a schematic plan view of the first conductive layer in FIG. 13a. In an exemplary implementation mode, the first conductive layer may be called a first gate metal (GATE1) layer.

In an exemplary implementation mode, the pattern of the first conductive layer of each circuit unit in the display region at least includes a first scan signal line 21, a second scan signal line 22, a light emitting control line 23, and a first electrode plate 24 of a storage capacitor.

In an exemplary implementation mode, a shape of the first electrode plate 24 of the storage capacitor may be a rectangular shape, wherein corners of the rectangular shape may be provided with chamfers. There is an overlapping region between an orthographic projection of the first electrode plate 24 on the base substrate and an orthographic projection of the third active layer of the third transistor T3 on the base substrate. In an exemplary implementation mode, the first electrode plate 24 may serve as an electrode plate of the storage capacitor and a gate electrode of the third transistor T3 simultaneously.

In an exemplary implementation mode, the first scan signal line 21, the second scan signal line 22, and the light emitting control line 23 may be in a line shape of which a main body portion extends along a first direction X. The first scan signal line 21 and the second scan signal line 22 in the circuit unit in the M-th row may be located at a side of the first electrode plate 24 of the present circuit unit away from the circuit unit in the (M+1)-th row, the second scan signal line 22 is located at a side of the first scan signal line 21 of the present circuit unit away from the first electrode plate 24, and the light emitting control line 23 may be located at a side of the first electrode plate 24 of the present circuit unit close to the circuit unit in the (M+1)-th row.

In an exemplary implementation mode, the first scan signal line 21 may be provided with a gate block 21-1 protruding toward one side of the second scan signal line 22, and a region in which the first scan signal line 21 and the gate block 21-1 are overlapped with the second active layer may serve as a gate electrode of the second transistor T2, forming the second transistor T2 with a double-gate structure.

In an exemplary implementation mode, a region in which the first scan signal line 21 is overlapped with the fourth active layer 14 serves as a gate electrode of a fourth transistor T4. A region in which the second scan signal line 22 is overlapped with the first active layer may serve as a gate electrode of the first transistor T1 with a double-gate structure, and a region in which the second scan signal line 22 is overlapped with the seventh active layer serves as a gate electrode of the seventh transistor T7. A region where the light emitting control line 23 is overlapped with the fifth active layer 15 serves as a gate electrode of the fifth transistor T5, and a region where the light emitting control line 23 is overlapped with the sixth active layer 16 serves as a gate electrode of the sixth transistor T6.

In an exemplary implementation mode, patterns of the first conductive layer of the E1 region and the E2 region in FIG. 10 are substantially the same as the pattern of the first conductive layer of the E0 region.

In an exemplary implementation mode, after the pattern of the first conductive layer is formed, a conductive processing may be performed on the semiconductor layer by using the first conductive layer as a shield, the semiconductor layer in a region shielded by the first conductive layer forms channel regions of the first transistor T1 to the seventh transistor T7, and the semiconductor layer in a region not shielded by the first conductive layer is made to be conductive, that is, first regions and second regions of the first active layer to the seventh active layer are all made to be conductive.

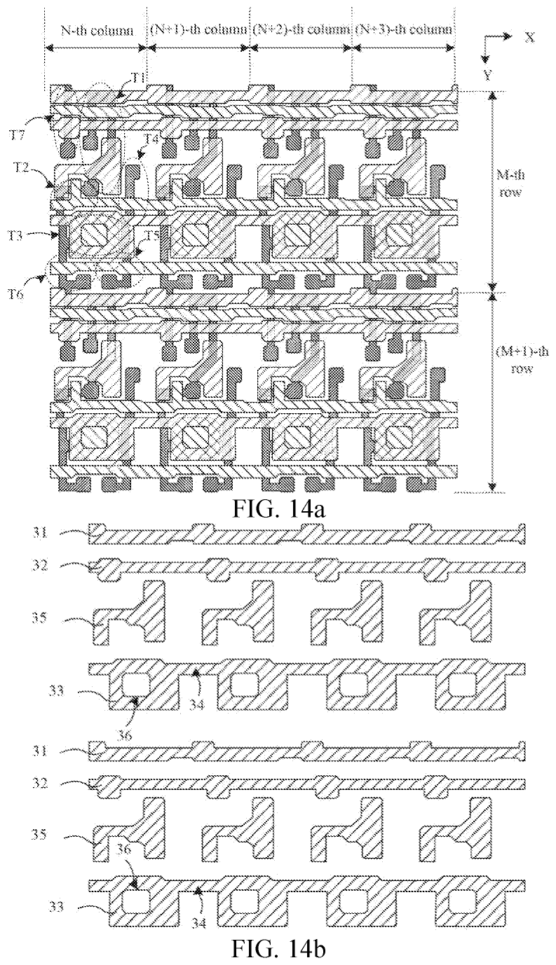

(3) A pattern of a second conductive layer is formed. In an exemplary implementation mode, forming the pattern of the second conductive layer may include: on the base substrate on which the aforementioned patterns are formed, sequentially depositing a third insulation thin film and a second conductive thin film, and patterning the second conductive thin film through a patterning process to form a third insulation layer covering the first conductive layer, and the pattern of the second conductive layer disposed on the third insulation layer, as shown in FIG. 14a and FIG. 14b, wherein FIG. 14a is an enlarged view of the E0 region in FIG. 10, and FIG. 14b is a schematic plan view of the second conductive layer in FIG. 14a. In an exemplary implementation mode, the second conductive layer may be called a second gate metal (GATE2) layer.

In an exemplary implementation mode, the pattern of the second conductive layer of each circuit unit in the display region at least includes: a first initial signal line 31, a second initial signal line 32, a second electrode plate 33, an electrode plate connection line 34, and a shielding electrode 35.

In an exemplary implementation mode, the first initial signal line 31 and the second initial signal line 32 may have a shape of a line of which a main body portion may extend along the first direction X. The first initial signal line 31 in the circuit unit in the M-th row may be located at a side of the second scan signal line 22 of the present circuit unit away from the first scan signal line 21, and the second initial signal line 32 may be located between the first scan signal line 21 and the second scan signal line 22 of the present circuit unit.

In an exemplary implementation mode, a contour shape of the second electrode plate 33 may be a rectangular shape, corners of the rectangular shape may be provided with chamfers, there is an overlapping region between an orthographic projection of the second electrode plate 33 on the base substrate and an orthographic projection of the first electrode plate 24 on the base substrate, the second electrode plate 33 serves as another electrode plate of the storage capacitor and is located between the first scan signal line 21 of the present circuit unit and the light emitting control line 24, and the first electrode plate 24 and the second electrode plate 33 constitute the storage capacitor of a pixel drive circuit.

In an exemplary implementation mode, the electrode plate connection line 34 may be disposed on one side of the second electrode plate 33 in the first direction X or an opposite direction of the first direction X, a first end of the electrode plate connection line 34 is connected with the second electrode plate 33 of the present circuit unit, and a second end of the electrode plate connection line 34, after extending along the first direction X or the opposite direction of the first direction X, is connected with a second electrode plate 33 of an adjacent circuit unit, so that second electrode plates 33 of adjacent circuit units in a unit row are connected with each other. In an exemplary implementation mode, second electrode plates of multiple circuit units in a unit row may be connected with each other to form an integral structure through an electrode plate connection line. The second electrode plates in the integral structure may be multiplexed as power supply signal connection lines, thus ensuring that multiple second electrode plates in a unit row have a same potential and being beneficial to improve uniformity of a panel, avoiding poor display of the display substrate, and ensuring a display effect of the display substrate.

In an exemplary implementation mode, the second electrode plate 33 is provided with an opening 36, and the opening 36 may be located in a middle of the second electrode plate 33. The opening 36 may be rectangular and enables the second electrode plate 33 to form an annular structure. The opening 36 exposes the third insulation layer covering the first electrode plate 24, and an orthographic projection of the first electrode plate 24 on the base substrate contains an orthographic projection of the opening 36 on the base substrate. In an exemplary implementation mode, the opening 36 is configured to accommodate a first via formed subsequently, and the first via is located within the opening 36 and exposes the first electrode plate 24, so that a second electrode of the first transistor T1 formed subsequently is connected with the first electrode plate 24.

In an exemplary implementation mode, the shielding electrode 35 may be located between the first scan signal line 21 and the second initial signal line 32 of the present circuit unit, and the shielding electrode 35 is configured to be connected with a first power supply line formed subsequently. An orthographic projection of the shielding electrode 35 on the base substrate is at least partially overlapped with orthographic projections of the second region of the first active layer and the first region of the second active layer on the base substrate, and the shielding electrode 35 is configured to shield an influence of data voltage jump on a key node, avoiding an influence of data voltage jump on a potential of a key node of the pixel drive circuit, and improving a display effect.

In an exemplary implementation mode, patterns of the second conductive layer of the E1 region and the E2 region in FIG. 10 are substantially the same as the pattern of the second conductive layer of the E0 region.

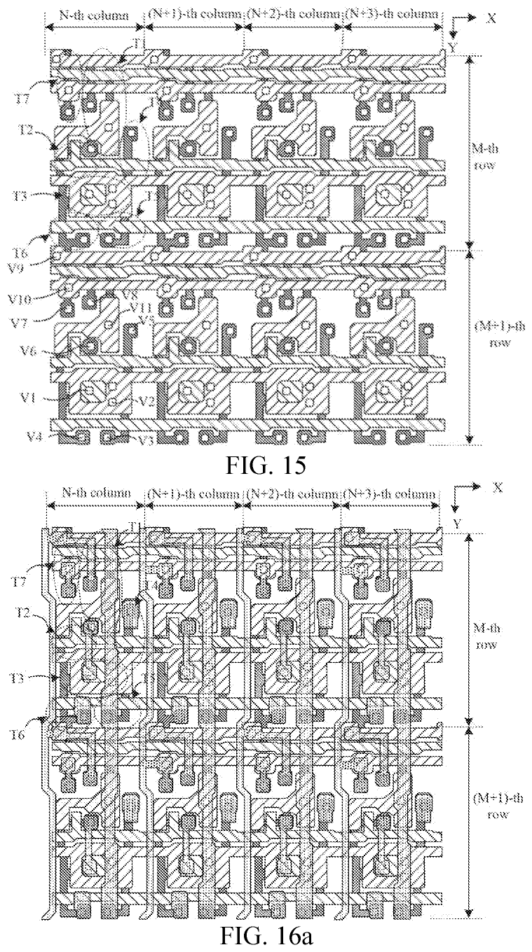

(4) A pattern of a fourth insulation layer is formed. In an exemplary implementation mode, forming a pattern of a fourth insulation layer may include: depositing a fourth insulation thin film on the base substrate on which the aforementioned patterns are formed, and patterning the fourth insulation thin film using a patterning process, to form a fourth insulation layer covering the second conductive layer, wherein multiple vias are disposed in each circuit unit, as shown in FIG. 15, and FIG. 15 is an enlarged view of the E0 region in FIG. 10.

In an exemplary implementation mode, the plurality of vias of each circuit unit in the display region at least includes a first via V1, a second via V2, a third via V3, a fourth via V4, a fifth via V5, a sixth via V6, a seventh via V7, an eighth via V8, a ninth via V9, a tenth via V10, and an eleventh via V11.

In an exemplary implementation mode, an orthographic projection of the first via V1 on the base substrate is located within a range of an orthographic projection of the opening 36 of the second electrode plate 33 on the base substrate, the fourth insulation layer and the third insulation layer within the first via V1 are etched away to expose a surface of the first electrode plate 24, and the first via V1 is configured such that a second electrode of the first transistor T1 formed subsequently is connected with the first electrode plate 24 through the via.

In an exemplary implementation mode, an orthographic projection of the second via V2 on the base substrate is within a range of an orthographic projection of the second electrode plate 33 on the base substrate, the fourth insulation layer within the second via V2 is etched away to expose a surface of the second electrode plate 33, and the second via V2 is configured such that a first power supply line formed subsequently is connected with the second electrode plate 33 through the via. In an exemplary implementation mode, the second via V2 serving as a power supply via may be plural, and a plurality of second vias V2 may be sequentially arranged along the second direction Y, thereby increasing connection reliability between the first power supply line and the second electrode plate 33.

In an exemplary implementation mode, an orthographic projection of the third via V3 on the base substrate is within a range of an orthographic projection of the first region of the fifth active layer on the base substrate. The fourth insulation layer, the third insulation layer, and the second insulation layer within the third via V3 are etched away to expose a surface of the first region of the fifth active layer, and the third via V3 is configured such that the first power supply line formed subsequently is connected with the first region of the fifth active layer through the via.

In an exemplary implementation mode, an orthographic projection of the fourth via V4 on the base substrate is within a range of an orthographic projection of the second region of the sixth active layer (which is also the second region of the seventh active layer) on the base substrate. The fourth insulation layer, the third insulation layer, and the second insulation layer within the fourth via V4 are etched away to expose a surface of the second region of the sixth active layer, the fourth via V4 is configured such that a second electrode of the sixth transistor T6 (which is also a second electrode of the seventh transistor T7) formed subsequently is connected with the second region of the sixth active layer (which is also the second region of the seventh active layer) through the via.

In an exemplary implementation mode, an orthographic projection of the fifth via V5 on the base substrate is located within a range of an orthographic projection of a first region of the fourth active layer on the base substrate, the fourth insulation layer, the third insulation layer, and the second insulation layer within the fifth via V5 are etched away to expose a surface of the first region of the fourth active layer, and the fifth via V5 is configured such that a first electrode of the fourth transistor T4 formed subsequently is connected with the first region of the fourth active layer through the via.

In an exemplary implementation mode, an orthographic projection of the sixth via V6 on the base substrate is within a range of an orthographic projection of the second region of the first active layer (which is also the first region of the second active layer) on the base substrate. The fourth insulation layer, the third insulation layer, and the second insulation layer within the sixth via V6 are etched away to expose a surface of the second region of the first active layer, the sixth via V6 is configured such that the second electrode of the first transistor T1 (which is also the first electrode of the second transistor T2) formed subsequently is connected with the second region of the first active layer (which is also the first region of the second active layer) through the via.

In an exemplary implementation mode, an orthographic projection of the seventh via V7 on the base substrate is within the range of an orthographic projection of the first region of the seventh active layer on the base substrate, the fourth insulation layer, the third insulation layer, and the second insulation layer within the seventh via V7 are etched away to expose a surface of the first region of the seventh active layer, and the seventh via V7 is configured such that a first electrode of the seventh transistor T7 subsequently formed is connected with the first region of the seventh active layer through the via.

In an exemplary implementation mode, an orthographic projection of the eighth via V8 on the base substrate is within a range of an orthographic projection of the first region of the first active layer on the base substrate, the fourth insulation layer, the third insulation layer, and the second insulation layer within the eighth via V8 are etched away to expose a surface of the first region of the first active layer. The eighth via V8 is configured such that a first electrode of the first transistor T1 subsequently formed is connected with the first region of the first active layer through the via.

In an exemplary implementation mode, an orthographic projection of the ninth via V9 on the base substrate is within a range of an orthographic projection of the first initial signal line 31 on the base substrate, the fourth insulation layer within the ninth via V9 is etched away to expose a surface of the first initial signal line 31. The ninth via V9 is configured such that a first electrode of the first transistor T1 subsequently formed is connected with the first initial signal line 31 through the via.

In an exemplary implementation mode, an orthographic projection of the tenth via V10 on the base substrate is within a range of an orthographic projection of the second initial signal line 32 on the base substrate, the fourth insulation layer within the tenth via V10 is etched away to expose a surface of the second initial signal line 32. The tenth via V10 is configured such that a first electrode of the seventh transistor T7 formed subsequently is connected with the second initial signal line 32 through the via.

In an exemplary implementation mode, an orthographic projection of the eleventh via V11 on the base substrate is within a range of an orthographic projection of the shielding electrode 35 on the base substrate. The fourth insulation layer within the eleventh via V11 is etched away to expose a surface of the shielding electrode 35, and the eleventh via V11 is configured such that a first power supply line subsequently formed is connected with the shielding electrode 35 through the via.

In an exemplary implementation mode, patterns of vias of the E1 region and the E2 region in FIG. 10 are substantially the same as patterns of vias of the E0 region.

(5) A pattern of a third conductive layer is formed. In an exemplary implementation mode, forming a third conductive layer may include: depositing a third conductive thin film on the base substrate on which the above-mentioned patterns are formed, and patterning the third conductive thin film using a patterning process to form a third conductive layer disposed on the fourth insulation layer, as shown in FIGS. 16a and 16b, FIG. 16a is an enlarged view of the E0 region in FIG. 10, and FIG. 16b is a schematic plan view of the third conductive layer in FIG. 16a. In an exemplary implementation mode, the third conductive layer may be referred to as a first source-drain metal (SD1) layer.

In an exemplary implementation mode, the pattern of the third conductive layer of a plurality of circuit units in the display region may include a first connection electrode 41, a second connection electrode 42, a third connection electrode 43, a fourth connection electrode 44, a fifth connection electrode 45, a first power supply line 46, and an initial connection line 47.

In an exemplary implementation mode, a shape of the first connection electrode 41 may be a strip shape extending along the second direction Y, a first end of the first connection electrode 41 is connected with the first electrode plate 24 through the first via V1, and a second end of the first connection electrode 41 is connected with the second region of the first active layer (which is also the first region of the second active layer) through the sixth via V6. In an exemplary implementation mode, the first connection electrode 41 may serve as the second electrode of the first transistor T1 and the first electrode of the second transistor T2, so that the first electrode plate 24, the second electrode of the first transistor T1, and the first electrode of the second transistor T2 have a same potential (a second node N2).

In an exemplary implementation mode, a shape of the second connection electrode 42 may be a rectangular shape, and the fourth connection electrode 44 is connected with the first region of the fourth active layer through the fifth via V5. In an exemplary implementation mode, the fourth connection electrode 44 may serve as a first electrode of the fourth transistor T4 and the fourth connection electrode 44 is configured to be connected with a data signal line formed subsequently.

In an exemplary implementation mode, the third connection electrode 43 may be in a rectangular shape, and the third connection electrode 43 is connected with the second region of the sixth active layer (which is also the second region of the seventh active layer) through the fourth via V4. In an exemplary implementation mode, the third connection electrode 43 may serve as a second electrode of the sixth transistor T6 and a second electrode of the seventh transistor T7, so that the second electrode of the sixth transistor T6 and the second electrode of the seventh transistor T7 have a same potential, and the third connection electrode 43 is configured to be connected with a first anode connection electrode formed subsequently.

In an exemplary implementation mode, the fourth connection electrode 44 may be in a shape of a strip with a main body portion extending along the second direction Y, a first end of the fourth connection electrode 44 is connected with the first region of the seventh active layer through the seventh via V7, and a second end of the fourth connection electrode 44 is connected with the second initial signal line 32 through the tenth via V10. In an exemplary implementation mode, the third fourth electrode 44 may serve as the first electrode of the seventh transistor T7, thereby achieving that the second initial signal line 32 writes a second initial signal into the seventh transistor T7.

In an exemplary implementation mode, the fifth connection electrode 45 may be in a shape of a broken line, a first end of the fifth connection electrode 45 is connected with the first region of the first active layer through the eighth via V8, and a second end of the fifth connection electrode 45 is connected with the first initial signal line 31 through the ninth via V9. The fifth connection electrode 45 may serve as the first electrode of the first transistor T1, thereby achieving that the first initial signal line 31 writes a first initial signal into the first electrode of the first transistor T1.

In an exemplary implementation mode, the first power supply line 46 may be in a shape of a line with a main body portion extending along the second direction Y. The first power supply line 46 is connected with the second electrode plate 33 through the second via V2 on one hand, is connected with the fifth active layer through the third via V3 on another hand, and is connected with the shielding electrode 35 through the eleventh via V11 on yet another hand, so that the first electrode of the fifth transistor T5 and the second electrode plate 33 have a same potential. The first power supply line 46 is configured to continuously provide a high power supply voltage signal (VDD), and may be referred to as a high voltage power supply line. Since the shielding electrode 35 is connected with the first power supply line 46, and at least a partial region of the shielding electrode 35 is located between the first connection electrode 41 (which serves as the second electrode of the first transistor T1 and the first electrode of the second transistor T2, i.e., a second node N2) and the second connection electrode 42 (which serves as a second electrode of the fourth transistor T4), the shielding electrode 35 may effectively shield an influence of data voltage jump on a key node in the pixel drive circuit, avoiding an influence of data voltage jump on a potential of the key node of the pixel drive circuit, and improving a display effect.

In an exemplary implementation mode, first power supply lines 46 of each circuit unit may be designed with unequal widths, and the first power supply lines 46 designed with the unequal widths may not only facilitate a layout of a pixel structure, but also reduce a parasitic capacitance between a first power supply line and a data signal line.

In an exemplary implementation mode, the initial connection line 47 may be in a shape of a broken line with a main body portion extending along the second direction Y, and is disposed at a side of the first connection electrode 41 away from the first power supply line 46, and the initial connection line 47 is configured to connect the first initial signal line 31 or the second initial signal line 32 to form a mesh communication structure for transmitting a first initial signal or a second initial signal.

In an exemplary implementation mode, the initial connection line 47 in a circuit unit in an odd-numbered column may be connected with the fifth connection electrode 45, the initial connection line 47 in a circuit unit in an even-numbered column may be connected with the fourth connection electrode 44, or the initial connection line 47 in the circuit unit in an odd-numbered column may be connected with the fourth connection electrode 44, and the initial connection line 47 in the circuit unit in an even-numbered column may be connected with the fifth connection electrode 45.

In an exemplary implementation mode, initial connection lines 47 in an N-th column and an (N+2)-th column may be connected with fifth connection electrodes 45 of a plurality of circuit units in the unit column, and since the fifth connection electrode 45 is connected with the first initial signal line 31 through a via, an interconnection of the initial connection line 47 with the first initial signal line 31 is achieved. A plurality of first initial signal lines 31 extending along the first direction X and a plurality of initial connection lines 47 extending along the second direction Y form initial signal lines in a mesh communication structure, which not only may effectively reduce a resistance of a first initial signal line and reduce voltage drop of a first initial signal, but also may effectively improve uniformity of first initial signals in the display substrate, effectively improve display uniformity and improve display attribute and display quality.

In an exemplary implementation mode, initial connection lines 47 in an (N+1)-th column and an (N+3)-th column may be connected with fourth connection electrodes 44 of a plurality of circuit units in the unit column. Since the fourth connection electrode 44 is connected with the second initial signal line 32 through a via, an interconnection of the initial connection line 47 and the second initial signal line 32 is achieved. A plurality of second initial signal lines 32 extending along the first direction X and a plurality of initial connection lines 47 extending along the second direction Y form initial signal lines in a mesh communication structure, which not only may effectively reduce a resistance of a second initial signal line and reduce voltage drop of a second initial signal, but also may effectively improve uniformity of second initial signals in the display substrate, effectively improve display uniformity and improve display attribute and display quality.

The present disclosure simultaneously achieves a mesh layout of an initial signal line transmitting a first initial signal and an initial signal line transmitting a second initial signal by forming the initial signal line transmitting the first initial signal into a mesh structure and forming the initial signal line transmitting the second initial signal into a mesh structure, which not only effectively reduces resistances of the first initial signal line and the second initial signal line, reduces voltage drop of a first initial voltage and a second initial voltage, but also effectively improves uniformity of the first initial voltage and the second initial voltage in the display substrate, effectively improves display uniformity, and improves display attribute and display quality.

In some possible exemplary implementation modes, initial connection lines 47 may be disposed to be connected with the first initial signal line 31 and the second initial signal line 32 respectively, in an odd-numbered row and even-numbered row manner. For example, an initial connection line 47 in a circuit unit in an odd-numbered row may be connected with the fifth connection electrode 45, an initial connection line 47 in a circuit unit in an even-numbered row may be connected with the fourth connection electrode 44, or the initial connection line 47 in the circuit unit in the odd-numbered row may be connected with the fourth connection electrode 44, and the initial connection line 47 in the circuit unit in the even-numbered row may be connected with the fifth connection electrode 45, which is not limited here in the present disclosure.

In an exemplary implementation mode, the pattern of the third conductive layer of the E1 region and the E2 region in FIG. 10 are substantially the same as the pattern of the third conductive layer of the E0 region.

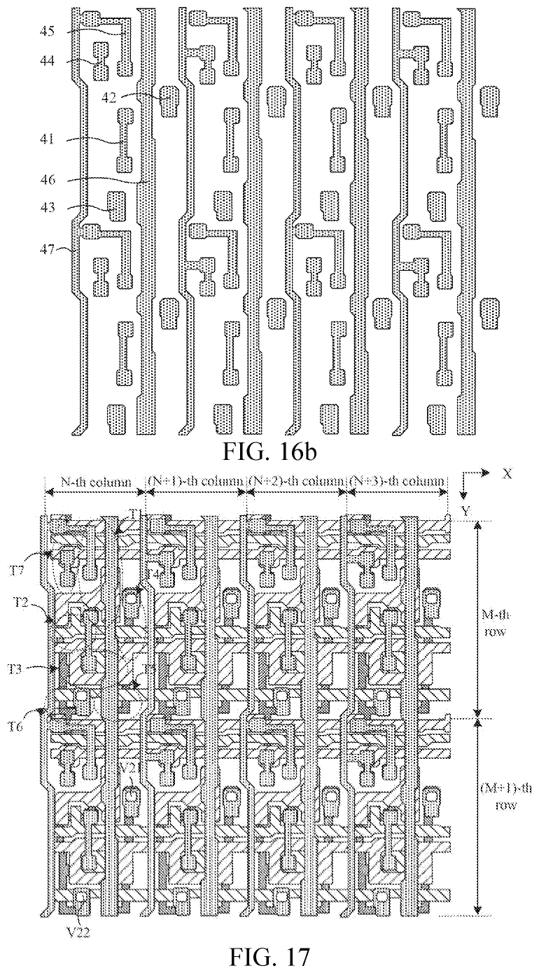

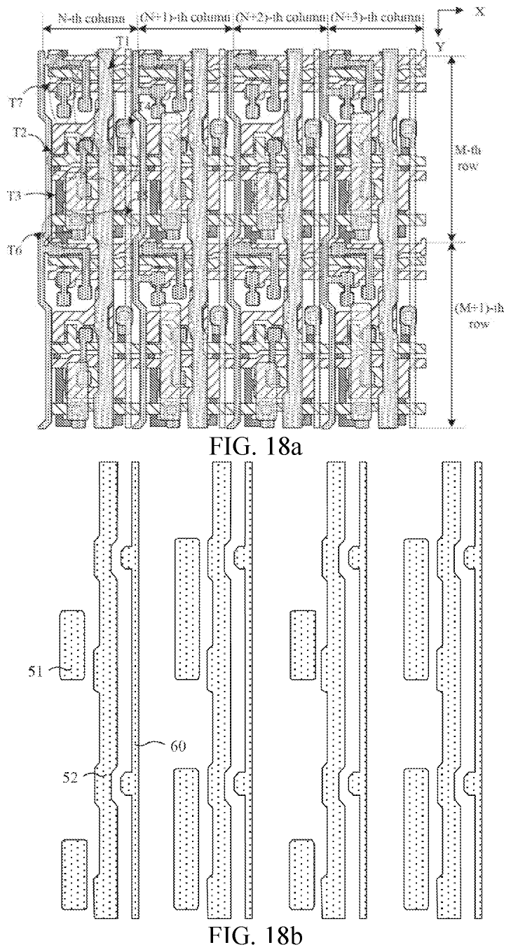

(6) Patterns of a fifth insulation layer and a first planarization layer are formed. In an exemplary implementation mode, forming patterns of a fifth insulation layer and a first planarization layer may include: first depositing a fifth insulation thin film on the base substrate on which the aforementioned patterns are formed, then coating a first planarization thin film, and patterning the first planarization thin film and the fifth insulation thin film using a patterning process, to form a fifth insulation layer covering the third conductive layer and the first planarization layer disposed on the fifth insulation layer, wherein the fifth insulation layer and the first planarization layer are provided with a plurality of vias, as shown in FIG. 17, which is an enlarged view of the E0 region in FIG. 10.

In an exemplary implementation mode, a plurality of vias of a plurality of circuit units in the display region include at least a twenty-first via V21 and a twenty-second via V22.

In an exemplary implementation mode, an orthographic projection of the twenty-first via V21 on the base substrate is within a range of an orthographic projection of the second connection electrode 42 on the base substrate, the first planarization layer and the fifth insulation layer within the twenty-first via V21 are removed to expose a surface of the second connection electrode 42, and the twenty-first via V21 is configured such that a data signal line formed subsequently is connected with the second connection electrode 42 through the via.

In an exemplary implementation mode, an orthographic projection of the twenty-second via V22 on the base substrate is within a range of an orthographic projection of the third connection electrode 43 on the base substrate, the first planarization layer and the fifth insulation layer within the twenty-second via V22 are removed to expose a surface of the third connection electrode 43, and the twenty-second via V22 is configured such that a first anode connection electrode formed subsequently is connected with the third connection electrode 43 through the via.

In an exemplary implementation mode, patterns of vias of the E1 region and the E2 region in FIG. 10 are substantially the same as patterns of vias of the E0 region.

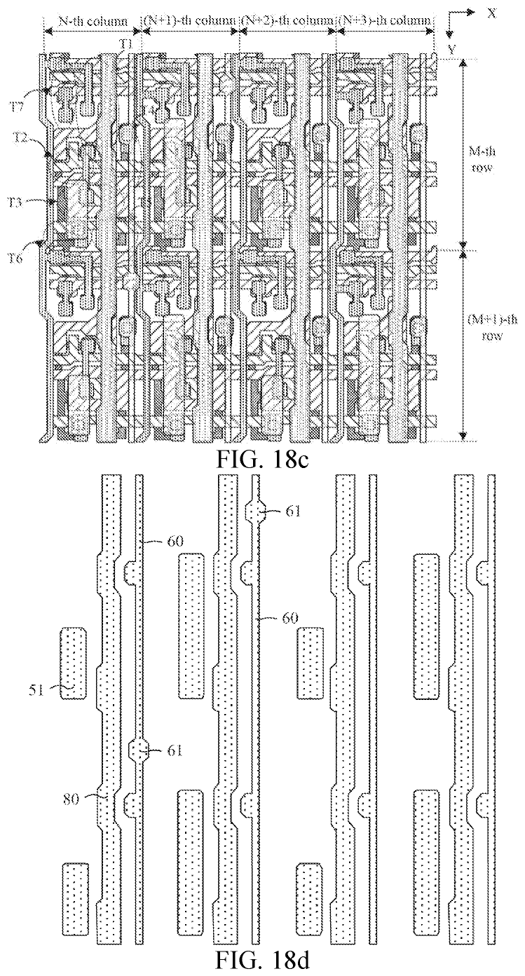

(7) A pattern of a fourth conductive layer is formed. In an exemplary implementation mode, forming a pattern of a fourth conductive layer may include: depositing a fourth conductive thin film on the base substrate on which the above-mentioned patterns are formed, patterning the fourth conductive thin film using a patterning process to form a fourth conductive layer disposed on the first planarization layer, as shown in FIGS. 18a to 18d, wherein FIG. 18a is an enlarged view of the E0 region and the E2 region in FIG. 10, FIG. 18b is a schematic plan view of the fourth conductive layer in FIG. 18a, FIG. 18c is an enlarged view of the E1 region in FIG. 10, and FIG. 18d is a schematic plan view of the fourth conductive layer in FIG. 18c. In an exemplary implementation mode, the fourth conductive layer may be referred to as a second source-drain metal (SD2) layer.

In an exemplary implementation mode, the pattern of the fourth conductive layer of a plurality of circuit units in the display region each include a first anode connection electrode 51, a data signal line 60, and a second power supply line 80.

In an exemplary implementation mode, the first anode connection electrode 51 may have a shape of a strip extending along the second direction Y, and the first anode connection electrode 51 is connected with the third connection electrode 43 through the twenty-second via V22. In an exemplary implementation mode, the first anode connection electrode 51 is configured to be connected with a second anode connection electrode subsequently formed. Shapes and positions of first anode connection electrodes 51 in the plurality of circuit units may be different in order to adapt to a connection with a subsequently formed anode.

In an exemplary implementation mode, the data signal line 60 may have a shape of a straight line with a main body portion extending along the second direction Y, and the data signal line 60 is connected with the second connection electrode 42 through the twenty-first via V21. Since the second connection electrode 42 is connected with the first region of the fourth active layer through a via, thereby achieving that the data signal line 60 writes a data signal into a first electrode of the fourth transistor T4.

In an exemplary implementation mode, the second power supply line 80 may be in a shape of a broken line with a main body portion extends along the second direction Y, and the second power supply line 80, as a low-voltage power supply line of the present disclosure, is configured to continuously provide a low power supply voltage signal (VSS) to a light emitting device formed subsequently.

In an exemplary implementation mode, an orthographic projection of the second power supply line 80 on the base substrate is at least partially overlapped with an orthographic projection of the first power supply line 46 on the base substrate. Since both the first power supply line 46 and the second power supply line 80 transmit constant voltage signals, they may be overlapped, which may effectively improve a transmittance and space utilization of the display substrate.

In an exemplary implementation mode, a region of an orthographic projection of the first power supply line 46 on the base substrate has a first area, and a region in which an orthographic projection of the second power supply line 80 on the base substrate is overlapped with the orthographic projection of the first power supply line 46 on the base substrate has a first overlapping area, and the first overlapping area may be greater than 80% of the first area.

In an exemplary implementation mode, the orthographic projection of the first power supply line 46 on the base substrate may be within a range of the orthographic projection of the second power supply line 80 on the base substrate.

In an exemplary implementation mode, structures of the first anode connection electrode 51, the second power supply line 80, and the data signal line 60 in the first region, the second region, and the third region are substantially the same.

In an exemplary implementation mode, the pattern of the fourth conductive layer of the second region (E2 region) and the third region (E0 region) of the display region are substantially the same, including only the first anode connection electrode 51, the data signal line 60, and the second power supply line 80, while the pattern of the fourth conductive layer of a plurality of circuit units in the first region (E1 region) of the display region may further include the data connection electrode 61.

In an exemplary implementation mode, the data connection electrode 61 may be disposed in some circuit units of the first region, a shape of the data connection electrode 61 may be a rectangular shape, the data connection electrode 61 is connected with the data signal line 60, and the data connection electrode 61 is configured to be connected with a first connection line formed subsequently.

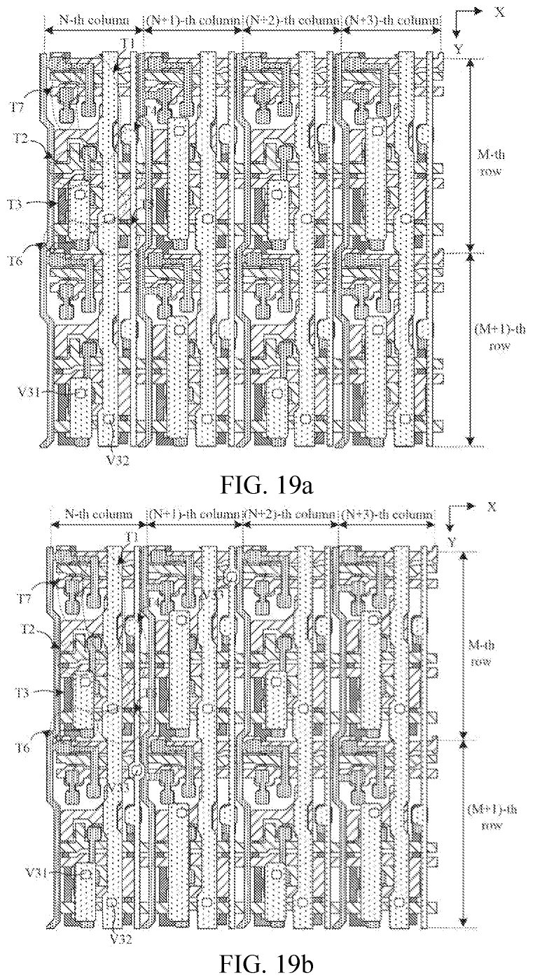

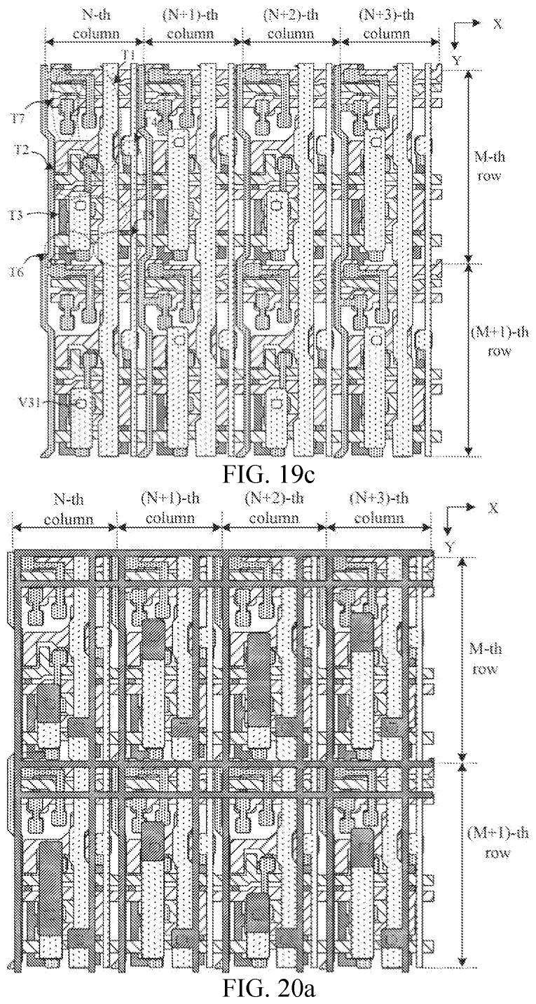

(8) A pattern of a second planarization layer is formed. In an exemplary implementation mode, forming a pattern of a second planarization layer may include: on the base substrate on which the aforementioned patterns are formed, coating a second planarization thin film, and patterning the second planarization layer using a patterning process to form a second planarization layer covering the fourth conductive layer, wherein the second planarization layer is provided with multiple vias, as shown in FIGS. 19a to 19c, FIG. 19a is an enlarged view of the E0 region in FIG. 10, FIG. 19b is an enlarged view of the E1 region in FIG. 10, and FIG. 19c is an enlarged view of the E2 region in FIG. 10.

In an exemplary implementation mode, a plurality of circuit units in the display region each include a thirty-first via V31.

In an exemplary implementation mode, an orthographic projection of the thirty-first via V31 on the base substrate is located within a range of an orthographic projection of the first anode connection electrode 51 on the base substrate, the second planarization layer within the thirty-first via V31 is removed to expose a surface of the first anode connection electrode 51, and the thirty-first via V31 is configured such that a subsequently formed second anode connection electrode is connected with the first anode connection electrode 51 through the via. Positions of thirty-first vias V31 in the plurality of circuit units may be different in order to adapt to a connection with a subsequently formed anode.

As shown in FIG. 19a, in an exemplary implementation mode, the plurality of circuit units in the third region (E0 region) of the display region may further include a thirty-second via V32.

In an exemplary implementation mode, an orthographic projection of the thirty-second via V32 on the base substrate is within a range of an orthographic projection of the second power supply line 80 on the base substrate, the second planarization layer within the thirty-second via V32 is removed to expose a surface of the second power supply line 80, and the thirty-second via V32 is configured such that a second power supply trace formed subsequently is connected with the second power supply line 80 through the via.

As shown in FIG. 19b, in an exemplary implementation mode, the plurality of circuit units in the first region (E1 region) of the display region may further include a thirty-second via V32 and a thirty-third via V33.

In an exemplary implementation mode, a structure of the thirty-second via V32 in the first region is substantially the same as that of the thirty-second via V32 in the third region.

In an exemplary implementation mode, an orthographic projection of the thirty-third via V33 on the base substrate is within a range of an orthographic projection of the data connection electrode 61 on the base substrate, the second planarization layer within the thirty-third via V33 is removed to expose a surface of the data connection electrode 61, and the thirty-third via V33 is configured such that a first connection line formed subsequently is connected with the data connection electrode 61 through the via.

As shown in FIG. 19c, in an exemplary implementation mode, a plurality of circuit units in the second region (E2 region) of the display region include only a thirty-first via V31.

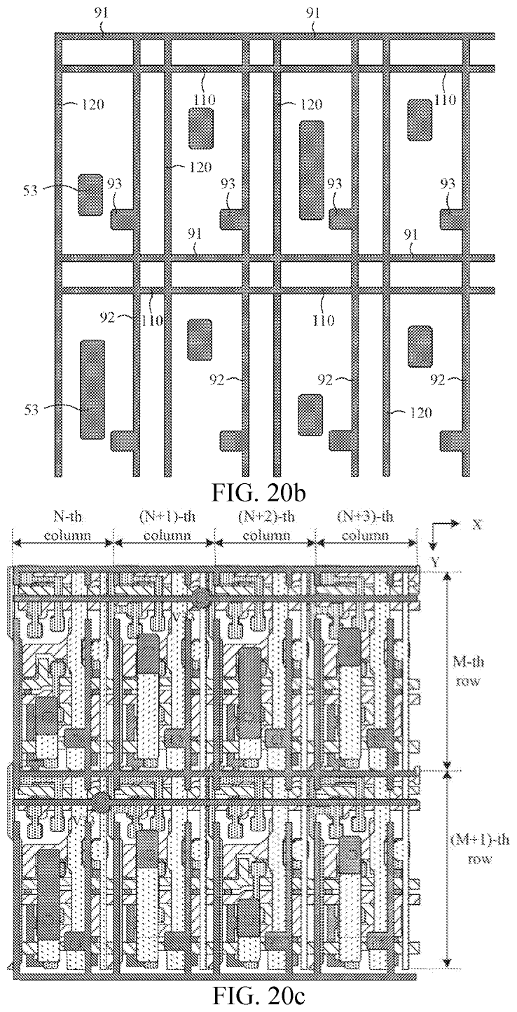

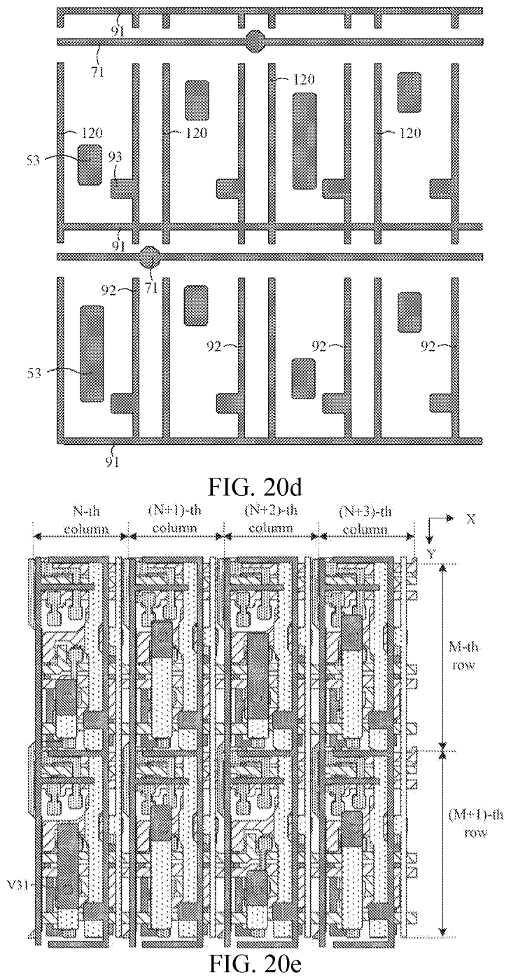

(9) A pattern of a fifth conductive layer is formed. In an exemplary implementation mode, forming the pattern of the fifth conductive layer may include: on the base substrate on which the aforementioned patterns are formed, depositing a fifth conductive thin film, and patterning the fifth conductive thin film using a patterning process to form a fifth conductive layer disposed on the second planarization layer, as shown in FIGS. 20a to 20f, wherein FIG. 20a is an enlarged view of the E0 region in FIG. 10, FIG. 20b is a schematic plan view of the fifth conductive layer in FIG. 20a, FIG. 20c is an enlarged view of the E1 region in FIG. 10, FIG. 20d is a schematic plan view of the fifth conductive layer in FIG. 20c, FIG. 20e is an enlarged view of the E2 region in FIG. 10, and FIG. 20f is a schematic plan view of the fifth conductive layer in FIG. 20e. In an exemplary implementation mode, the fifth conductive layer may be referred to as a third source-drain metal (SD3) layer.

In an exemplary implementation mode, the pattern of the fifth conductive layers of the multiple circuit units in the display region each include a second anode connection electrode 53.

In an exemplary implementation mode, a shape of the second anode connection electrode 53 may be a rectangular shape and the second anode connection electrode 53 is connected with the first anode connection electrode 51 through the thirty-first via V31. In an exemplary implementation mode, the second anode connection electrode 53 is configured to be connected with an anode formed subsequently. Shapes and positions of second anode connection electrodes 53 in the plurality of circuit units may be different in order to adapt to a connection with a subsequently formed anode.

As shown in FIGS. 20a and 20b, the pattern of the fifth conductive layer of a plurality of circuit units in the third region (E0 region) of the display region further includes a first power supply trace 91, a second power supply trace 92, a power supply connection electrode 93, a first compensation line 110, and a second compensation line 120.

In an exemplary implementation mode, the first power supply traces 91 may have a shape of a straight line with a main body portion extending along the first direction X, and first power supply traces 91 in circuit units adjacent in the first direction X in the third region are of an interconnected integral structure.

In an exemplary implementation mode, an orthographic projection of the first power supply trace 91 on the base substrate and an orthographic projection of the first initial signal line 31 on the base substrate are at least partially overlapped, which may effectively improve a transmittance and space utilization of the display substrate.

In an exemplary implementation mode, a region of an orthographic projection of the first power supply trace 91 on the base substrate has a third area, and a region where the orthographic projection of the first power supply trace 91 on the base substrate is overlapped with an orthographic projection of the first initial signal line 31 on the base substrate has a third overlapping area, and the third overlapping area may be greater than 80% of the third area.

In an exemplary implementation mode, the second power supply traces 92 may have a shape of a straight line with a main body portion extending along the second direction Y, and second power supply traces 92 in circuit units adjacent in the second direction Y in the third region are of an interconnected integral structure.

In an exemplary implementation mode, an orthographic projection of the second power supply trace 92 on the base substrate is at least partially overlapped with an orthographic projection of the second electrode plate 33 of the storage capacitor on the base substrate.

In an exemplary implementation mode, a plurality of second power supply traces 92 and a plurality of first power supply traces 91 in the third region are of an interconnected integral structure and constitute a grid-like power supply lead.

In an exemplary implementation mode, the power supply connection electrode 93 may have a rectangular shape, the power supply connection electrode 93 may be disposed at a side of the second power supply trace 92 away from the data signal line 60 (i.e., at a side close to the second power supply line 80) and connected with the second power supply trace 92, an orthographic projection of the power supply connection electrode 93 on the base substrate is at least partially overlapped with an orthographic projection of a low-voltage power supply line 52 on the base substrate, and the power supply connection electrode 93 is connected with the second power supply line 80 through the thirty-second via V32, achieving a connection between the grid-like power supply lead and the second power supply line 80.

In an exemplary implementation mode, the first compensation line 110 may have a shape of a straight line with a main body portion extending along the first direction X, and first compensation lines 110 in circuit units adjacent in the first direction X in the third region are of an interconnected integral structure.

In an exemplary implementation mode, an orthographic projection of the first compensation line 110 on the base substrate and an orthographic projection of the second initial signal line 32 on the base substrate are at least partially overlapped, which may effectively improve a transmittance and space utilization of the display substrate.

In an exemplary implementation mode, a region of an orthographic projection of the first compensation line 110 on the base substrate has a fourth area, and a region where the orthographic projection of the first compensation line 110 on the base substrate is overlapped with the orthographic projection of the second initial signal line 32 on the base substrate has a fourth overlapping area, and the fourth overlapping area may be greater than 80% of the fourth area.

In an exemplary implementation mode, the second compensation line 120 may have a shape of a straight line with a main body portion extending along the second direction Y, and second compensation lines 120 in circuit units adjacent in the second direction Y in the third region are of an interconnected integral structure.

In an exemplary implementation mode, an orthographic projection of the second compensation line 120 on the base substrate and an orthographic projection of the initial connection line 47 on the base substrate are at least partially overlapped, which may effectively improve a transmittance and space utilization of the display substrate.

In an exemplary implementation mode, a region of an orthographic projection of the second compensation line 120 on the base substrate has a fifth area, and a region where the orthographic projection of the second compensation line 120 on the base substrate is overlapped with the orthographic projection of the initial connection line 47 on the base substrate has a fifth overlapping area, and the fifth overlapping area may be greater than 80% of the fifth area.

In an exemplary implementation mode, a plurality of first compensation lines 110 and a plurality of second compensation lines 120 in the third region are of an interconnected integral structure to form a grid-like compensation line, and the first compensation lines 110 and the second compensation lines 120 are configured such that the pattern of the fifth conductive layer of the third region and the pattern of the fifth conductive layer of the first region and the second region present similar morphologies, which may not only improve uniformity of preparation processes, but also enable different regions to achieve substantially a same display effect under transmitted light and reflected light, effectively avoiding poor appearance of the display substrate, and improving display attribute and display quality.

In an exemplary implementation mode, the plurality of first compensation lines 110 and a plurality of second power supply traces 92 are interconnected, and the plurality of second compensation lines 120 and a plurality of first power supply traces 91 are interconnected, thereby achieving interconnection of the grid-like power supply lead and the grid-like compensation line.

In an exemplary implementation mode, in the third region, at least one circuit unit may be provided with at least one first power supply trace 91, at least one second power supply trace 92, at least one first compensation line 110, and at least one second compensation line 120, the first power supply trace 91 may be disposed at a side of the circuit unit in the second direction Y, the first compensation line 110 may be disposed at a side of the circuit unit in an opposite direction of the second direction Y, the second power supply trace 92 may be disposed at a side of the second power supply line 80 in the first direction X, and the second compensation line 120 may be disposed at a side of the second power supply line 80 in an opposite direction of the first direction X.

In an exemplary implementation mode, an orthographic projection of the second compensation line 120 on the base substrate is at least partially overlapped with an orthographic projection of a dummy line on the base substrate.

As shown in FIGS. 20c and 20d, the pattern of the fifth conductive layer of the plurality of circuit units in the first region (E1 region) of the display region further includes a first connection line 71, a first power supply trace 91, a second power supply trace 92, a power supply connection electrode 93, and a second compensation line 120.

In an exemplary implementation mode, the first connection line 71 may have a shape of a straight line with a main body portion extending along the first direction X and the first connection line 71 is connected with the data connection electrode 61 through the thirty-third via V33. Since the data connection electrode 61 is connected with the data signal line 60, thereby achieving a connection between the first connection line 71 and the data signal line 60.

In an exemplary implementation mode, an orthographic projection of the first connection line 71 on the base substrate is at least partially overlapped with an orthographic projection of the second initial signal line 32 on the base substrate. Since the first connection line 71 is located in the fifth conductive layer (SD3) and the second initial signal line 32 is located in the second conductive layer (GATE2), and the first planarization layer and the second planarization layer which are relatively thick are disposed between them, there will be no crosstalk between the first connection line 71 transmitting a data signal and the second initial signal line 32 transmitting an initial voltage signal. By overlapping the first connection line 71 and the second initial signal line 32, a transmittance and space utilization of the display substrate may be effectively improved.

In an exemplary implementation mode, a region of an orthographic projection of the first connection line 71 on the base substrate has a second overlapping area, and a region where the orthographic projection of the first connection line 71 on the base substrate is overlapped with an orthographic projection of the second initial signal line 32 on the base substrate has a second area, and the second overlapping area may be greater than 80% of the second area.

In an exemplary implementation mode, first connection lines 71 in circuit units adjacent in the first direction X in the first region are of an interconnected integral structure.

In an exemplary implementation mode, in at least one unit row including a circuit unit of the first region and a circuit unit of the third region, the first connection line 71 of the first region and the first compensation line 110 of the third region may be located on a same straight line extending along the first direction X, so that traces of the first region and traces of the third region present similar morphologies, which may not only improve uniformity of preparation processes, but also enable different regions to achieve substantially a same display effect under transmitted light and reflected light, effectively avoiding poor appearance of the display substrate, and improving display attribute and display quality.

In an exemplary implementation mode, in at least one unit column including a circuit unit of the first region and a circuit unit of the third region, the first power supply trace 91 of the first region and the first power supply trace 91 of the third region may be located on a same straight line extending along the second direction Y, the power supply connection electrode 93 of the first region and the power supply connection electrode 93 of the third region may be located on a same straight line extending along the second direction Y, first power supply traces 91 in circuit units adjacent in the first direction X in the first region are of an interconnected integral structure, and the power supply connection electrode 93 is connected with the second power supply line 80 through the thirty-second via V32.

In an exemplary implementation mode, in at least one unit column including a circuit unit of the first region and a circuit unit of the third region, the second power supply trace 92 of the first region and the second power supply trace 92 of the third region may be located on a same straight line extending along the second direction Y, the second compensation line 120 of the first region and the second compensation line 120 of the third region may be located on a same straight line extending along the second direction Y, except that second power supply traces 92 and second compensation lines 120 of circuit units adjacent in the second direction Y in the first region are discontinuous, i.e., second power supply traces 92 in circuit units adjacent in the second direction Y are disposed at intervals, and second compensation lines 120 in the circuit units adjacent in the second direction Y are disposed at intervals, so that a first connection line 71 is disposed between breaks of a second power supply trace 92 and a second compensation line 120.

As shown in FIGS. 20e and 20f, the pattern of the fifth conductive layer of the plurality of circuit units in the second region (E2 region) of the display region further includes a second connection line 72, a dummy connection electrode 73, and a first compensation line 110.

In an exemplary implementation mode, the second connection line 72 may have a shape of a straight line with a main body portion extending along the second direction Y, a first end of the second connection line 72 is connected with a leading out line located in a lead region, and a second end of the second connection line 72 is connected with the first connection line 71 located in the display region, so that the first connection line 71 and the second connection line 72 connected with each other constitute a data connection line.

In an exemplary implementation mode, second connection lines 72 in circuit units adjacent in the second direction Y in the second region are of an interconnected integral structure.

In an exemplary implementation mode, in at least one unit column including a circuit unit of the second region and a circuit unit of the third region, a first side connection line in the second connection line 72 of the second region and the second power supply trace 92 of the third region may be located on a same straight line extending along the second direction Y, and a second side connection line in the second connection line 72 of the second region and the second compensation line 120 of the third region may be located on a same straight line extending along the second direction Y, so that traces of the second region and traces of the third region present similar morphologies, which may not only improve uniformity of preparation processes, but also enable different regions to achieve substantially a same display effect under transmitted light and reflected light, effectively avoiding poor appearance of the display substrate, and improving display attribute and display quality.

In an exemplary implementation mode, the dummy connection electrode 73 may have a rectangular shape, the dummy connection electrode 73 may be disposed at a side of the second connection line 72 away from the data signal line 60 (i.e., at a side close to the second power supply line 80) and connected with the second connection line 72, and an orthographic projection of the dummy connection electrode 73 on the base substrate is at least partially overlapped with an orthographic projection of the low-voltage power supply line 52 on the base substrate.

In an exemplary implementation mode, in at least one unit row including a circuit unit of the second region and a circuit unit of the third region, the dummy connection electrode 73 of the second region and the power supply connection electrode 93 of the third region may be located on a same straight line extending along the first direction X, in at least one unit column including a circuit unit of the second region and a circuit unit of the third region, the dummy connection electrode 73 of the second region and the power supply connection electrode 93 of the third region may be located on a same straight line extending along the second direction Y, i.e., a position and a shape of the dummy connection electrode 73 in the circuit unit of the second region are substantially the same as a position and a shape of the power supply connection electrode 93 in the circuit unit of the third region, except that the dummy connection electrode 73 is not connected with the second power supply line 80 through a via, and the dummy connection electrode 73 is configured such that patterns of the fifth conductive layer of the second region and the third region present similar morphologies, which may not only improve uniformity of preparation processes, but also enable different regions to achieve substantially a same display effect under transmitted light and reflected light, effectively avoiding poor appearance of the display substrate, and improving display attribute and display quality.

In an exemplary implementation mode, the first compensation line 110 may have a shape of a straight line segment with a main body portion extending along the first direction X, a first end of the first compensation line 110 is connected with the second connection line 72, and a second end of the first compensation line 110 extends along the first direction X or an opposite direction of the first direction X.

In an exemplary implementation mode, at least two second connection lines 72 and two first compensation lines 110 may be disposed in at least one circuit unit of the second region. The two second connection lines 72 may include a first side connection line and a second side connection line, the first side connection line may be disposed between the second power supply line 80 and the data signal line 60, and the second side connection line may be disposed at a side of the second power supply line 80 away from the data signal line 60. The at least two first compensation lines 110 may include at least one first side compensation line and at least one second side compensation line, a first end of the first side compensation line is connected with the first side connection line, a second end of the first side compensation line extends toward a direction close to the second side connection line, a first end of the second side compensation line is connected with the second side connection line, and a second end of the second side compensation line extends toward a direction close to the first side connection line, so that the two first compensation lines 110 in the circuit unit form an interdigital structure.

In an exemplary implementation mode, in at least one unit row including a circuit unit of the second region and a circuit unit of the third region, a first side compensation line of the second region and the first power supply trace 91 of the third region may be located on a same straight line extending along the first direction X, except that first side compensation lines are disposed at intervals among a plurality of circuit units of one unit row.

In an exemplary implementation mode, in at least one unit row including a circuit unit of the second region and a circuit unit of the first region, a second side compensation line of the second region and the first connection line 71 of the first region may be located on a same straight line extending along the first direction X, except that second side compensation lines are disposed at intervals among a plurality of circuit units of one unit row.

In an exemplary implementation mode, in at least one unit row including a circuit unit of the first region, a circuit unit of the second region, and a circuit unit of the third region, the first power supply trace 91 of the first region, the first side compensation line in the first compensation line 110 of the second region, and the first power supply trace 91 of the third region may be located on a same straight line extending along the first direction X, the first connection line 71 of the first region, the second side compensation line in the first compensation line 110 of the second region, and the first compensation line 110 of the third region may be located on a same straight line extending along the first direction X, and the power supply connection electrode 93 of the first region, the dummy connection electrode 73 of the second region, and the power supply connection electrode 93 of the third region may be located on a same straight line extending along the first direction X.

In an exemplary implementation mode, in at least one unit column including a circuit unit of the first region, a circuit unit of the second region, and a circuit unit of the third region, the second power supply trace 92 of the first region, the first side connection line in the second connection line 72 of the second region, and the second power supply trace 92 of the third region may be located on a same straight line extending along the second direction Y, the second compensation line 120 of the first region, the second side connection line of the second connection line 72 in the second region, and the second compensation line 120 of the third region may be located on a same straight line extending along the second direction Y, and the power supply connection electrode 93 of the first region, the dummy connection electrode 73 of the second region, and the power supply connection electrode 93 of the third region may be located on a same straight line extending along the second direction Y.

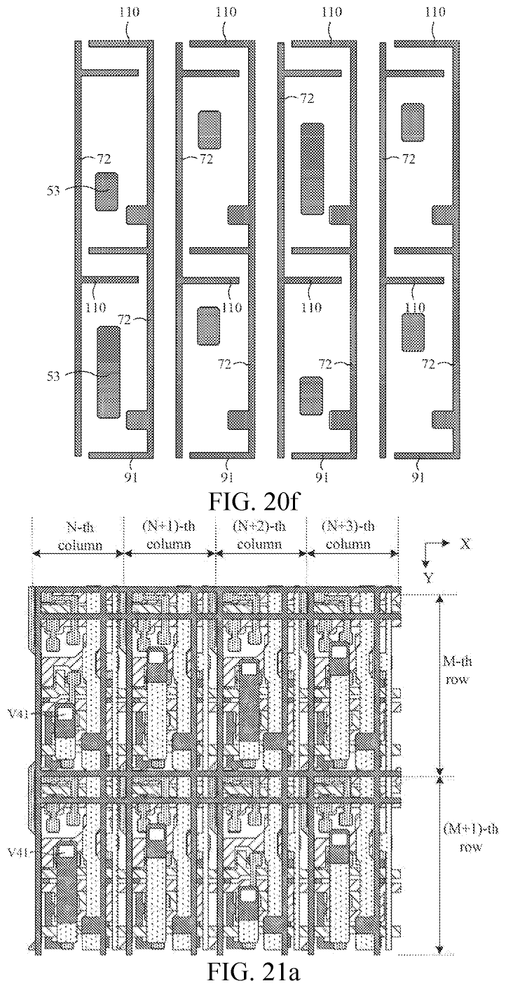

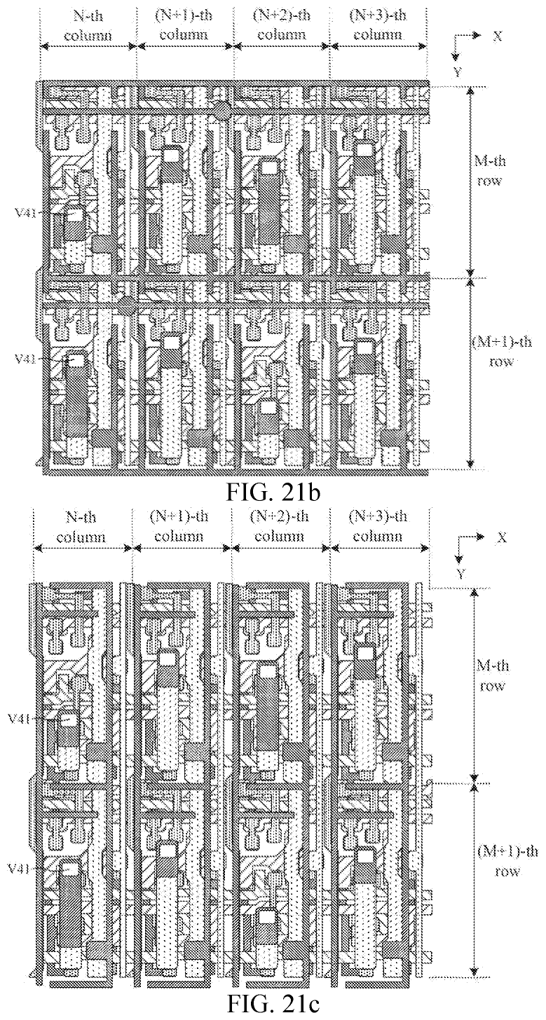

(10) A pattern of a third planarization layer is formed. In an exemplary implementation mode, forming a pattern of a third planarization layer may include: coating a third planarization thin film on the base substrate on which the above-mentioned patterns are formed, patterning the third planarization thin film using a patterning process to form a third planarization layer covering the fifth conductive layer, wherein the third planarization layer is provided with a plurality of vias, as shown in FIGS. 21a to 21c, wherein FIG. 21a is an enlarged view of the E0 region in FIG. 10, FIG. 21b is an enlarged view of the E1 region in FIG. 10, and FIG. 21c is an enlarged view of the E2 region in FIG. 10.

In an exemplary implementation mode, vias of each circuit unit in the display region include at least a forty-first via V41. In an exemplary implementation mode, an orthographic projection of the forty-first via V41 on the base substrate is within a range of an orthographic projection of the second anode connection electrode 53 on the base substrate, the third planarization layer within the forty-first via V41 is removed to expose a surface of the second anode connection electrode 53, and the forty-first via V41 is configured such that an anode formed subsequently is connected with the second anode connection electrode 53 through the via. Positions of forty-first vias V41 in a plurality of circuit units may be different in order to adapt to a connection with a subsequently formed anode.

In an exemplary implementation mode, patterns of vias of the first region, the second region, and the third region are substantially the same.

So far, a drive circuit layer has been prepared on the base substrate. On a plane parallel to the display substrate, the drive circuit layer may include a plurality of circuit units, each of which may include a pixel drive circuit, and a first scan signal line, a second scan signal line, a light emitting control line, a data signal line, a first power supply line, a second power supply line, a first initial signal line, and a second initial signal line that are connected with the pixel drive circuit. On a plane perpendicular to the display substrate, the drive circuit layer may include a first insulation layer, a semiconductor layer, a second insulation layer, a first conductive layer, a third insulation layer, a second conductive layer, a fourth insulation layer, a third conductive layer, a fifth insulation layer, a first planarization layer, a fourth conductive layer, a second planarization layer, a fifth conductive layer, and a third planarization layer that are sequentially stacked on the base substrate.

In an exemplary implementation mode, the base substrate may be a flexible base substrate, or a rigid base substrate. The rigid base substrate may be made of, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation mode, the flexible base substrate may include a first flexible material layer, a first inorganic material layer, a semiconductor layer, a second flexible material layer, and a second inorganic material layer which are stacked, wherein materials of the first flexible material layer and the second flexible material layer may be Polyimide (PI), Polyethylene Terephthalate (PET), or a surface-treated polymer soft film, or the like, materials of the first inorganic material layer and the second inorganic material layer may be Silicon Nitride (SiNx) or Silicon Oxide (SiOx), or the like, for improving a water and oxygen resistance capability of the base substrate, and a material of the semiconductor layer may be amorphous silicon (a-si).

In an exemplary implementation mode, the first conductive layer, the second conductive layer, the third conductive layer, the fourth conductive layer, and the fifth conductive layer may be made of a metal material, such as any one or more of Argentum (Ag), Copper (Cu), Aluminum (Al), and Molybdenum (Mo), or an alloy material of the aforementioned metals, such as an Aluminum-Neodymium alloy (AlNd) or a Molybdenum-Niobium alloy (MoNb), and may be of a single-layer structure, or a multi-layer composite structure such as Mo/Cu/Mo. The first insulation layer, the second insulation layer, the third insulation layer, the fourth insulation layer, and the fifth insulation layer may be made of any one or more of Silicon Oxide (SiOx), Silicon Nitride (SiNx), and Silicon Oxynitride (SiON), and may be a single layer, a multi-layer, or a composite layer. The first insulation layer may be referred to as a buffer layer, the second insulation layer and the third insulation layer may be referred to as a Gate Insulation (GI) layer, the fourth insulation layer may be referred to as an Interlayer Dielectric (ILD) layer, and the fifth insulation layer may be referred to as a Passivation (PVX) layer. The first planarization layer, the second planarization layer, and the third planarization layer may be made of an organic material, such as a resin. The semiconductor layer may be made of a material, such as an amorphous Indium Gallium Zinc Oxide material (a-IGZO), Zinc Oxynitride (ZnON), Indium Zinc Tin Oxide (IZTO), amorphous Silicon (a-Si), polycrystalline Silicon (p-Si), hexthiophene, or polythiophene, that is, the present disclosure is applicable to a transistor manufactured based on an oxide technology, a silicon technology, or an organic matter technology.

In an exemplary implementation mode, after preparation of the drive circuit layer is completed, a light emitting structure layer is prepared on the drive circuit layer, and a preparation process of the light emitting structure layer may include following operations.

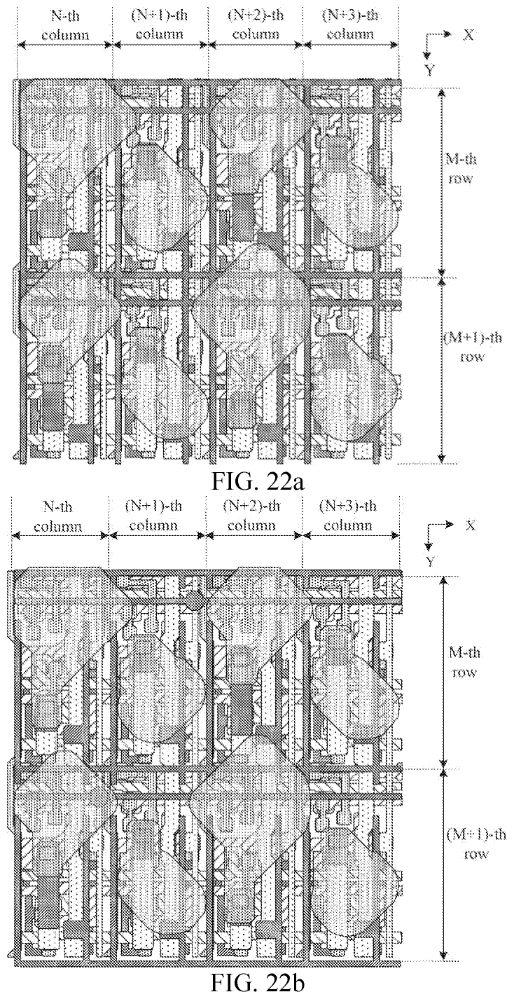

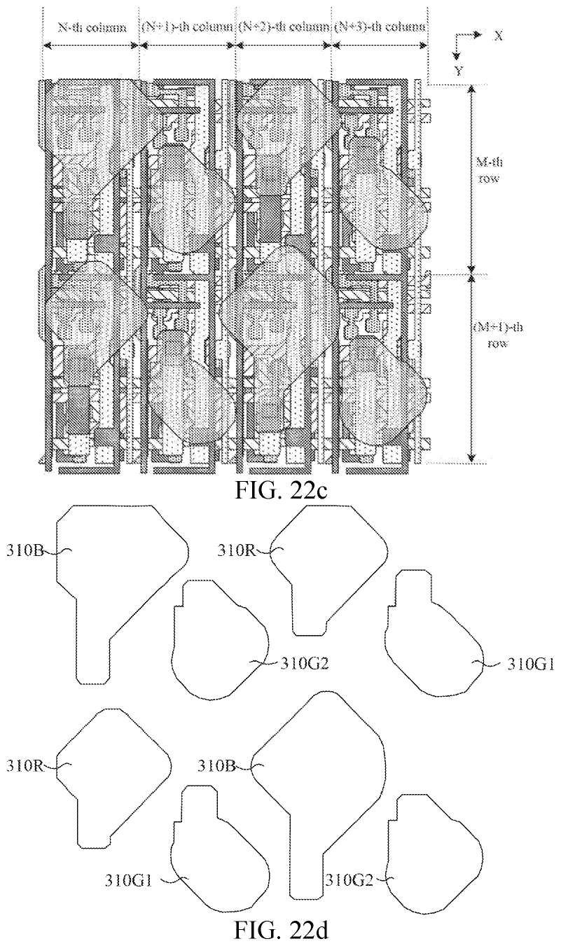

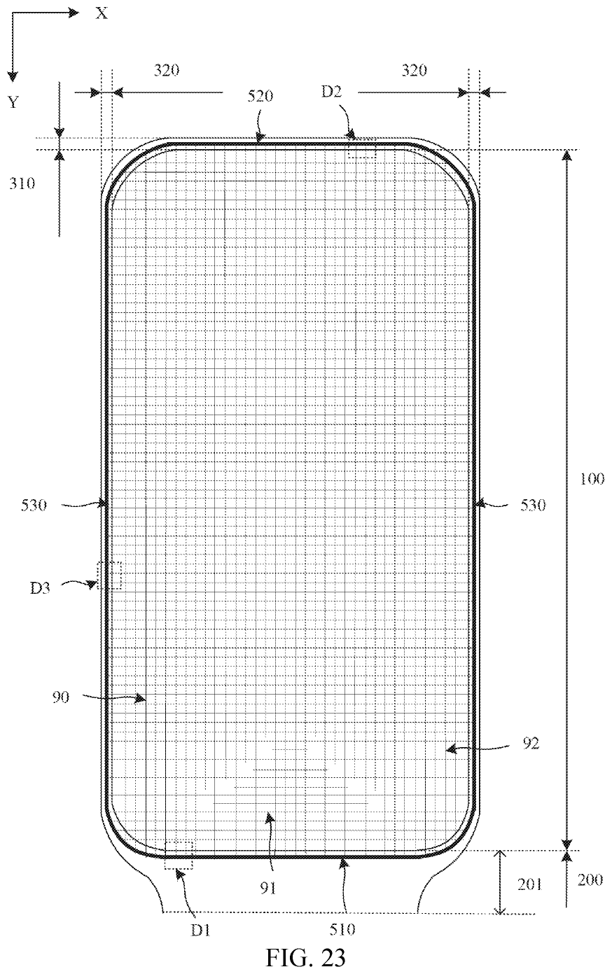

(11) A pattern of an anode conductive layer is formed. In an exemplary implementation mode, forming a pattern of an anode conductive layer may include: depositing an anode conductive thin film on the base substrate on which the above-mentioned patterns are formed, patterning the anode conductive thin film using a patterning process to form the pattern of the anode conductive layer disposed on the third planarization layer, as shown in FIGS. 22a to 22d, wherein FIG. 22a is an enlarged view of the E0 region in FIG. 10, FIG. 22b is an enlarged view of the E1 region in FIG. 10, FIG. 22c is an enlarged view of the E2 region in FIG. 10, and FIG. 22d is a schematic plan view of the anode conductive layer in FIG. 22a.

In an exemplary implementation mode, the anode conductive layer may be of a single-layer structure, such as Indium Tin Oxide (ITO) or Indium Zinc Oxide (IZO), or may be of a multi-layer composite structure, such as ITO/Ag/ITO.

In an exemplary implementation mode, the pattern of the anode conductive layer may include a first anode 301R of a red light emitting device, a second anode 301B of a blue light emitting device, a third anode 301G1 of a first green light emitting device, and a fourth anode 301G2 of a second green light emitting device. A region where the first anode 301R is located may form a red sub-pixel R emitting red light, a region where the second anode 301B is located may form a blue sub-pixel B emitting blue light, a region where the third anode 301G1 is located may form a first green sub-pixel G1 emitting green light, and a region where the fourth anode 301G2 is located may form a second green sub-pixel G2 emitting green light.

In an exemplary implementation mode, the first anode 301A and the second anode 301B may be sequentially disposed along the second direction Y, the third anode 301C and the fourth anode 301D may be sequentially disposed along the second direction Y, and the third anode 301C and the fourth anode 301D may be disposed on one side of the first anode 301A and the second anode 301B in the first direction X. Or, the first anode 301A and the second anode 301B may be sequentially disposed along the first direction X, the third anode 301C and the fourth anode 301D may be sequentially disposed along the first direction X, and the third anode 301C and the fourth anode 301D may be disposed on one side of the first anode 301A and the second anode 301B in the second direction Y.

In an exemplary implementation mode, the first anode 301R, the second anode 301B, the third anode 301G1, and the fourth anode 301G2 may be connected with a second anode connection electrode 53 in a corresponding circuit unit through the forty-first via V41, respectively. Since each anode is connected with the second region of the sixth active layer (which is also the second region of the seventh active layer) through a second anode connection electrode, a first anode connection electrode, and a third connection electrode in one circuit unit, four anodes in one pixel unit are respectively connected with pixel drive circuits of four circuit units correspondingly, thereby achieving that a pixel drive circuit may drive a light emitting device to emit light.

In an exemplary implementation mode, shapes and positions of two second anodes 301B connected with pixel drive circuits in a circuit unit in an M-th row and an N-th column and a circuit unit in an (M+1)-th row and an (N+2)-th column, respectively, are the same, shapes and positions of two first anodes 301R connected with pixel drive circuits in a circuit unit in an M-th row and an (N+2)-th column and a circuit unit in an (M+1)-th row and an N-th column, respectively, are the same, and shapes and positions of two fourth anodes 301G2 connected with pixel drive circuits in a circuit unit in an M-th row and an (N+1)-th column and a circuit unit in an (M+1)-th row and an (N+3)-th column, respectively, are the same. Shapes and positions of two third anodes 301G1 connected with pixel drive circuits in a circuit unit in an M-th row and an (N+3)-th column and a circuit unit in an (M+1)-th row and an (N+1)-th column, respectively, are the same.

In an exemplary implementation mode, shapes and areas of anodes of four sub-pixels in one pixel unit may be the same or different, positional relationships between the four sub-pixels of one pixel unit and four circuit units in one circuit unit group may be the same or different, and shapes and positions of first anodes 301R, second anodes 301B, third anodes 301G1, and fourth anodes 301G2 in different pixel units may be the same or different, which is not limited here in the present disclosure.

In an exemplary implementation mode, at least one of the first anode 301A, the second anode 301B, the third anode 301C, and the fourth anode 301D may include a main body portion and a connection portion connected with each other, the main body portion may have a rectangular shape, a corner portion of the rectangular shape may be provided with an arc-shaped chamfer, the connection portion may have a shape of a strip extending along a direction away from the main body portion, and the connection portion is connected with the second anode connection electrode 53 through the forty-first via V41.

As shown in FIG. 22a, in the third region, orthographic projections of main body portions of the first anode 301A and the second anode 301B on the base substrate are at least partially overlapped with orthographic projections of one first power supply trace 91 and one first compensation line 110 on the base substrate, the orthographic projections of the main body portions of the first anode 301A and the second anode 301B on the base substrate are at least partially overlapped with orthographic projections of one second power supply trace 92 and two second compensation lines 120 on the base substrate, and orthographic projections of main body portions of the third anode 301C and the fourth anode 301D on the base substrate are at least partially overlapped with an orthographic projection of one second power supply trace 92 on the base substrate.

As shown in FIG. 22b, in the first region, orthographic projections of main body portions of the first anode 301A and the second anode 301B on the base substrate are at least partially overlapped with orthographic projections of one first power supply trace 91 and one first connection line 71 on the base substrate, the orthographic projections of the main body portions of the first anode 301A and the second anode 301B on the base substrate are at least partially overlapped with orthographic projections of one second power supply trace 92 and two second compensation lines 120 on the base substrate, and orthographic projections of main body portions of the third anode 301C and the fourth anode 301D on the base substrate are at least partially overlapped with an orthographic projection of one second power supply trace 92 on the base substrate.

As shown in FIG. 22c, in the second region, orthographic projections of main body portions of the first anode 301A and the second anode 301B on the base substrate are at least partially overlapped with orthographic projections of two first compensation lines 110 on the base substrate, the orthographic projections of the main body portions of the first anode 301A and the second anode 301B on the base substrate are at least partially overlapped with orthographic projections of three second connection lines 72 on the base substrate, and orthographic projections of main body portions of the third anode 301C and the fourth anode 301D on the base substrate are at least partially overlapped with an orthographic projection of one second connection line 72 on the base substrate.

In an exemplary implementation mode, comparing orthographic projections of the first anode 301A and the second anode 301B in the first region, the second region, and the third region on the base substrate, it may be seen that main body portions of the first anode 301A and the second anode 301B both are overlapped with two transverse lines (straight lines extending along the first direction X), and the main body portions of the first anode 301A and the second anode 301B both are overlapped with three vertical lines (straight lines extending along the second direction Y), so that transverse metal lines and longitudinal metal lines of a SD3 layer below the main body portions of the first anode 301A and the second anode 301B in three regions are substantially the same, planarization of the first anode 301A and the second anode 301B in the three regions may be ensured, and light emitting performance of a red light emitting device and a blue light emitting device in the three regions may be guaranteed to be substantially the same.

In an exemplary implementation mode, comparing orthographic projections of the third anode 301C and the fourth anode 301D in the first region, the second region, and the third region on the base substrate, it may be seen that orthographic projections of main body portions of the third anode 301C and the fourth anode 301D on the base substrate both are overlapped with one vertical line but are not overlapped with a transverse line, so that transverse metal lines and longitudinal metal lines of a SD3 layer below the main body portions of the third anode 301C and the fourth anode 301D in three regions are substantially the same, planarization of the third anode 301C and the fourth anode 301D in the three regions may be ensured, and light emitting performance of a first green light emitting device and a second green light emitting device in the three regions may be guaranteed to be substantially the same.

In an exemplary implementation mode, a subsequent preparation process may include: forming a pattern of a pixel definition layer at first, then forming an organic emitting layer using an evaporation process and inkjet printing process, then forming a cathode on the organic emitting layer, and then forming an encapsulation structure layer, wherein the encapsulation structure layer may include a first encapsulation layer, a second encapsulation layer, and a third encapsulation layer which are stacked, the first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the light emitting structure layer.

FIG. 23 is a schematic diagram of a planar structure of a power supply trace according to an exemplary embodiment of the present disclosure. As shown in FIG. 23, the display substrate may include a display region 100, a bonding region 200 located at a side of the display region 100 in the second direction Y, and a bezel region 300 located at another side of the display region 100. The bezel region 300 may include an upper bezel region 310 located at a side of the display region 100 in an opposite direction of the second direction Y (away from the bonding region 200), and a side bezel region 320 located at one side or two sides of the display region 100 in the first direction X. The display region 100 is provided with a power supply trace 90 with a mesh communication structure, the bonding region 200 is provided with a bonding lead 510, the upper bezel region 310 is provided with an upper bezel lead 520, and the side bezel region 320 is provided with a side bezel lead 530. The power supply trace 90 is connected with the bonding lead 510, the upper bezel lead 520, and the side bezel lead 530, respectively.

In an exemplary implementation mode, the bonding lead 510 of the bonding region 200, the upper bezel lead 520 of the upper bezel region 310, and the side bezel lead 530 of the side bezel region 320 may be of an interconnected integral structure.

In an exemplary implementation mode, power supply traces 90 of the display region 100 may include a plurality of first power supply traces 91 extending along the first direction X and a plurality of second power supply traces 92 extending along the second direction Y. The plurality of first power supply traces 91 may be sequentially disposed along the second direction Y, one end or two ends in the first direction X, after extending to the side bezel region 320, are connected with the side bezel lead 530, the plurality of second power supply traces 92 may be sequentially disposed along the first direction X, one end in the second direction Y, after extending to the bonding region 200, is connected with the bonding lead 510, and one end in an opposite direction of the second direction Y extends to the upper bezel region 310 and is connected with the upper bezel lead 520.

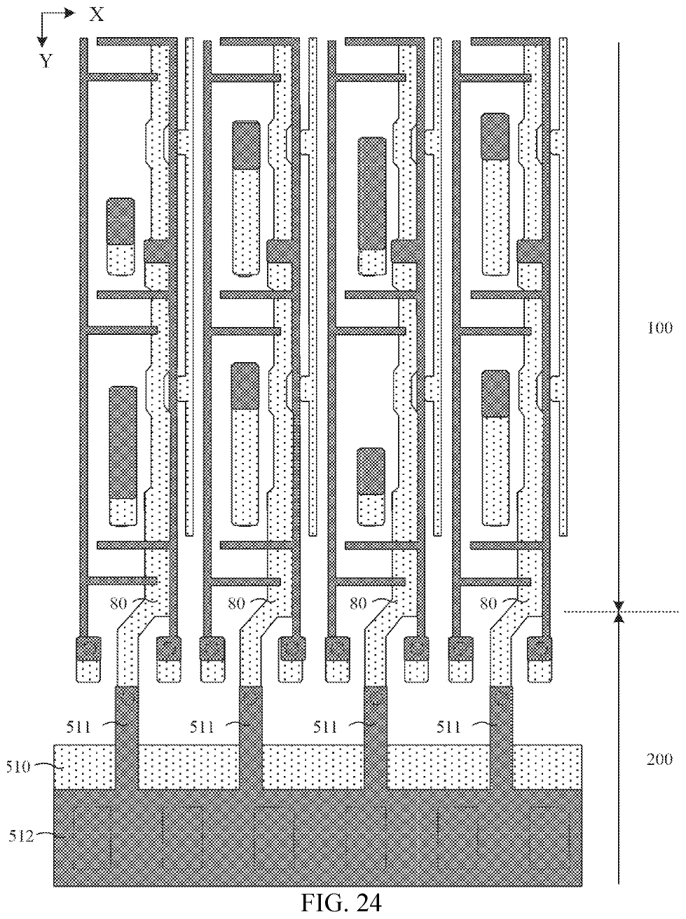

FIG. 24 is a schematic diagram of a connection between a power supply trace and a bonding lead according to an exemplary embodiment of the present disclosure, and is an enlarged region of a D1 region in FIG. 23. As shown in FIG. 24, the bonding region 200 may include at least a bonding lead 510, a first power supply connection line 511, and a first power supply pin 512.

In an exemplary implementation mode, the bonding lead 510 may be disposed in the fourth conductive (SD2) layer, the bonding lead 510 may have a shape of a strip extending along the first direction X, and the bonding lead 510 is configured to be connected with a power supply pad in a bonding pin.

In an exemplary implementation mode, the first power supply connection line 511 and the first power supply pin 512 may be disposed in the fifth conductive (SD3) layer, a first end of the first power supply connection line 511 is connected with the second power supply line 80 extending to the bonding region 200 through a via opened on the second planarization layer, a second end of the second power supply connection line 511, after extending toward a direction away from the display region, is directly connected with the first power supply pin 512, and the first power supply pin 512 is connected with the bonding lead 510 through a plurality of vias opened on the second planarization layer.

In an exemplary implementation mode, the first power supply connection line 511 may have a shape of a strip extending along the second direction Y, and the first power supply pin 512 may be connected with the second power supply line 80 through a plurality of first power supply connection lines 511.

In an exemplary implementation mode, the first power supply pin 512 may have a shape of a strip extending along the first direction X, so that the bonding lead 510 located in the fourth conductive layer and the first power supply pin 512 located in the fifth conductive layer form a double-layer power supply trace, minimizing voltage drop of a power supply signal and achieving low power consumption. The present disclosure may greatly reduce a width of a bonding lead by connecting a power supply trace of the display region with a bonding lead of the bonding region, which greatly reduces a width of the bonding region, and is beneficial to achieve full-screen display.

In an exemplary implementation mode, the first power supply connection line 511 and the first power supply pin 512 may be of an interconnected integral structure.

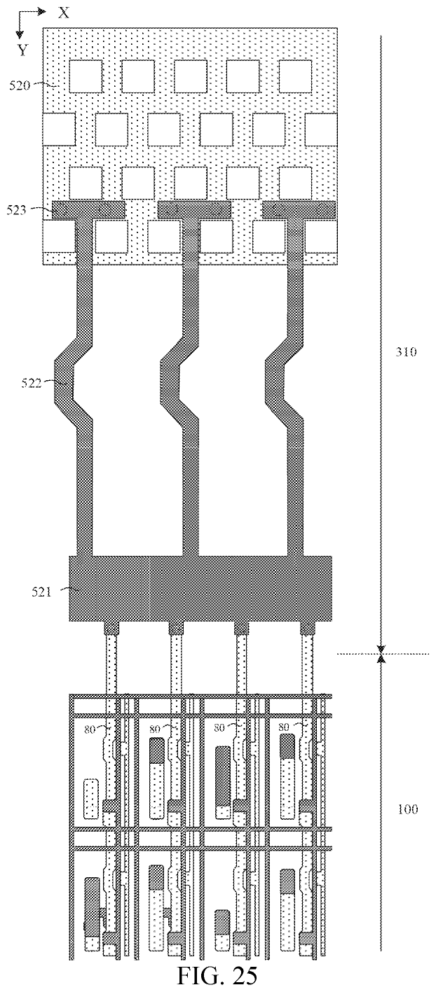

FIG. 25 is a schematic diagram of a connection between a power supply trace and an upper bezel lead according to an exemplary embodiment of the present disclosure, and is an enlarged region of a D2 region in FIG. 23. As shown in FIG. 25, the upper bezel region 310 may include at least an upper bezel lead 520, a second power supply connection strip 521, a second power supply connection line 522, and a second power supply pin 523.

In an exemplary implementation mode, the bezel lead 520 may be disposed in the fourth conductive (SD2) layer, the upper bezel lead 520 may have a shape of a strip extending along the first direction X, and the upper bezel lead 520 is configured to be connected with the bonding lead in the bonding region through the side bezel lead of the side bezel region.

In an exemplary implementation mode, the second power supply connection strip 521, the second power supply connection line 522, and the second power supply pin 523 may be disposed in the fifth conductive (SD3) layer. A first end of the second power supply connection strip 521 is connected with the second power supply line 80 extending to the upper bezel region 310 through a via opened on the second planarization layer. A second end of the second power supply connection strip 521 is connected with a first end of the second power supply connection line 522. A second end of the second power supply connection line 522, after extending toward a direction away from the display region, is connected with the second power supply pin 523. The second power supply pin 523 is connected with the upper bezel lead 520 through a plurality of vias opened on the second planarization layer. The present disclosure may greatly reduce a width of the upper bezel lead by connecting the power supply trace of the display region with the upper bezel lead of the upper bezel region, which greatly reduces a width of the upper bezel region, and is beneficial to achieve full-screen display.

In an exemplary implementation mode, the second power supply connection strip 521 may have a shape of a strip extending along the first direction X, the second power supply connection line 522 may have a shape of a strip extending along the second direction Y, the second power supply pin 523 may have a rectangular shape, and the second power supply connection strip 521 may be connected with the upper bezel lead 520 through a plurality of second power supply connection lines 522 and a plurality of second power supply pins 523.

In an exemplary implementation mode, the second power supply connection strip 521, the second power supply connection line 522, and the second power supply pin 523 may be of an interconnected integral structure.

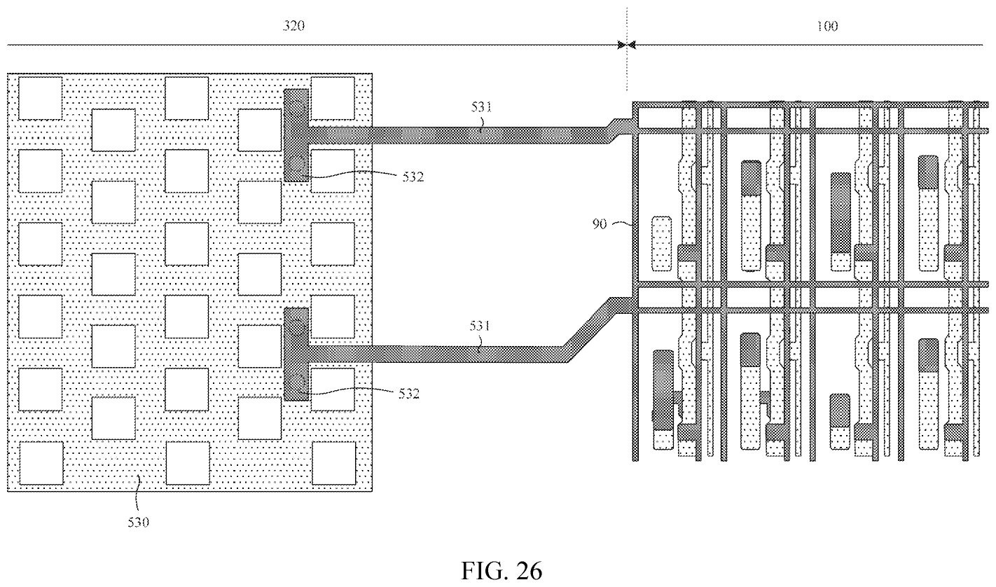

FIG. 26 is a schematic diagram of a connection between a power supply trace and a side bezel lead according to an exemplary embodiment of the present disclosure, and is an enlarged region of a D3 region in FIG. 23. As shown in FIG. 26, the side bezel region 320 may include at least a side bezel lead 530, a third power supply connection line 531, and a third power supply pin 532.

In an exemplary implementation mode, the side bezel lead 530 may be disposed in the fourth conductive (SD2) layer, the side bezel lead 530 may have a shape of a strip extending along the second direction Y, and the side bezel lead 530 is configured to be connected with the bonding lead 510 in the bonding region.

In an exemplary implementation mode, the third power supply connection line 531 and the third power supply pin 532 may be disposed in the fifth conductive (SD3) layer, a first end of the third power supply connection line 531 is connected with the power supply trace 90 in the display region 100 through a via opened on the second planarization layer, a second end of the third power supply connection line 531, after extending in a direction away from the display region, is directly connected with the third power supply pin 532, and the third power supply pin 532 is connected with the side bezel lead 530 through a plurality of vias opened on the second planarization layer. The present disclosure may greatly reduce a width of the side bezel lead by connecting the power supply trace of the display region with the side bezel lead of the side bezel region, which greatly reduces a width of the side bezel region, and is beneficial to achieve full-screen display.

In an exemplary implementation mode, the third power supply connection line 531 may have a shape of a broken line extending along the first direction X, the third power supply pin 532 may have a shape of a strip extending along the second direction Y, and the power supply trace 90 may be connected with the side bezel lead 530 through a plurality of third power supply connection lines 531 and the third power supply pin 532.

In an exemplary implementation mode, the third power supply connection line 531 and the third power supply pin 532 may be of an interconnected integral structure.

As may be seen from a structure and the preparation process of the display substrate described above, according to the present disclosure, a data connection line is disposed in the display region, so that a leading out line of the bonding region is connected with a data signal line through the data connection line. Therefore, there is no need to dispose a fan-shaped oblique line in the lead region, which reduces a length of the lead region effectively, reduces a width of a lower bezel greatly, increases a screen-to-body ratio, and is conducive to achieving full-screen display.

In a display substrate, a display region includes a trace region provided with a data connection line and a normal region not provided with a data connection line. Since the data connection line of the trace region has a relatively high reflection capability under irradiation of external light, while a reflection capability of another metal line in the normal region is relatively weak, appearance of the normal region is obviously different from appearance of the trace region, which leads to a problem of poor appearance of the display substrate, and poor appearance is more obvious especially when a screen is off or in low gray scale display. In an exemplary embodiment of the present disclosure, a second compensation line is disposed in the first region, a first compensation line is disposed in the second region, and a first compensation line and a second compensation line are disposed in the third region, which may not only enable different regions to have substantially a same structure and different regions to achieve basically a same display effect under transmitted light and reflected light, effectively avoiding poor appearance of the display substrate, but also enable transverse metal lines and longitudinal metal lines below anodes in the three regions to be substantially the same, which may ensure planarization of the anodes in the three regions substantially the same, ensure light emitting performance of light emitting devices substantially the same, avoid a color deviation of a large viewing angle, and improve display attribute and display quality.

In the present disclosure, a first power supply trace and a second power supply trace are disposed in the display region, and the first power supply trace and the second power supply trace form a power supply trace with a mesh communication structure, so that a structure of VSS in pixel is achieved, which not only may effectively reduce a resistance of a power supply trace, effectively reduce voltage drop of a low-voltage power supply signal, and achieve low power consumption, but also may effectively improve uniformity of power supply signals in the display substrate, effectively improve display uniformity, and improve display attribute and display quality. The present disclosure may greatly reduce a width of a power supply lead by connecting a power supply trace with the power supply lead in the bonding region and the bezel region, which greatly reduces a bezel width, and is beneficial to achieve full-screen display. The preparation process in the present disclosure may be compatible well with an existing preparation process, is simple in process implementation, is easy to implement, and has a high production efficiency, a low production cost, and a high yield.

The aforementioned structure shown in the present disclosure and the preparation process thereof are merely exemplary description. In an exemplary implementation mode, corresponding structures may be changed and patterning processes may be added or reduced according to actual needs, which is not limited here in the present disclosure.

In an exemplary implementation mode, the display substrate according to the present disclosure may be applied to a display apparatus with a pixel drive circuit, such as an OLED, a quantum dot display (QLED), a light emitting diode display (Micro LED or Mini LED), or a Quantum Dot Light Emitting Diode display (QDLED), which is not limited here in the present disclosure.

The present disclosure also provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present disclosure.

Although implementation modes disclosed in the present disclosure are described as above, the described contents are only implementation modes which are used for facilitating understanding of the present disclosure, but are not intended to limit the present disclosure. Any skilled person in the art to which the present disclosure pertains may make any modification and variation in a form and details of implementation without departing from the spirit and scope of the present disclosure. However, the patent protection scope of the present disclosure should be subject to the scope defined in the appended claims.

1. A display substrate, comprising a display region, wherein the display region comprises a drive circuit layer disposed on a base substrate and a light emitting structure layer disposed at a side of the drive circuit layer away from the base substrate, the drive circuit layer comprises a plurality of circuit units, a plurality of data signal lines, a plurality of data connection lines, a plurality of low-voltage power supply lines, and a plurality of power supply traces, the light emitting structure layer comprises a plurality of light emitting devices, the circuit units comprise pixel drive circuits, the data signal lines are configured to provide data signals to the pixel drive circuits, the low-voltage power supply lines are configured to continuously provide low power supply voltage signals to the light emitting devices; the data connection lines are connected with the data signal lines, and the power supply traces are connected with the low-voltage power supply lines.

2. The display substrate according to claim 1, wherein a data connection line comprises a first connection line extending along a first direction and a second connection line extending along a second direction, the first connection line is connected with the second connection line, a power supply trace comprises a first power supply trace extending along the first direction and a second power supply trace extending along the second direction, the first power supply trace is connected with the second power supply trace, the first direction and the second direction intersect; on a plane parallel to the base substrate, the display region comprises at least a first region provided with the first connection line, at least one circuit unit of the first region comprises the first connection line, the first power supply trace, and the second power supply trace, a data signal line and a low-voltage power supply line are in a shape of a line extending along the second direction, the first connection line is connected with the data signal line, the second power supply trace is disposed between the low-voltage power supply line and the data signal line, and the second power supply trace is connected with the low-voltage power supply line.

3. The display substrate according to claim 2, wherein the drive circuit layer comprises a plurality of conductive layers sequentially disposed on the base substrate; the first connection line and the second connection line are disposed in a same conductive layer, and the first connection line and the data signal line are disposed in different conductive layers; in at least one circuit unit of the first region, the first connection line is connected with the data signal line through a first connection hole;
or,
the drive circuit layer comprises a plurality of conductive layers sequentially disposed on the base substrate; the first power supply trace and the second power supply trace are disposed in a same conductive layer, and the second power supply trace and the low-voltage power supply line are disposed in different conductive layers; in at least one circuit unit of the first region, the second power supply line is connected with the low-voltage power supply line through a second connection hole.

4. (canceled)

5. The display substrate according to claim 2, wherein at least one circuit unit of the first region further comprises a power supply connection electrode, the power supply connection electrode is disposed at a side of the second power supply trace away from the data signal line and connected with the second power supply trace, an orthographic projection of the power supply connection electrode on the base substrate is at least partially overlapped with an orthographic projection of the low-voltage power supply line on the base substrate, and the power supply connection electrode is connected with the low-voltage power supply line through a second connection hole;
or,
at least one circuit unit of the first region further comprises a second compensation line extending along the second direction, the second compensation line is disposed at a side of the second power supply trace away from the data signal line, the second compensation line is connected with the first power supply trace, second compensation lines in circuit units adjacent in the second direction are disposed at intervals, and the first connection line is disposed between second compensation lines adjacent in the second direction.

6. The display substrate according to claim 2, wherein in the first region, first connection lines in circuit units adjacent in the first direction are connected with each other, and first power supply traces in the circuit units adjacent in the first direction are connected with each other;
or,
in the first region, second power supply traces in circuit units adjacent in the second direction are disposed at intervals, and the first connection line is disposed between second power supply traces adjacent in the second direction.

7-8. (canceled)

9. The display substrate according to claim 2, wherein on a plane parallel to the base substrate, the display region further comprises a second region provided with the second connection line, the second connection line is comprised in at least one circuit unit of the second region, and second connection lines in circuit units adjacent in the second direction are connected with each other.

10. The display substrate according to claim 9, wherein at least one circuit unit of the second region comprises two second connection lines, the two second connection lines comprise a first side connection line and a second side connection line, the first side connection line is disposed between the low-voltage power supply line and the data signal line, and the second side connection line is disposed at a side of the low-voltage power supply line away from the data signal line.

11. The display substrate according to claim 10, wherein at least one circuit unit of the second region further comprises a dummy connection electrode, the dummy connection electrode is disposed at a side of the second side connection line close to the first side connection line and connected with the second side connection line, and an orthographic projection of the dummy connection electrode on the base substrate is at least partially overlapped with an orthographic projection of the low-voltage power supply line on the base substrate.

12. The display substrate according to claim 11, wherein in at least one unit column comprising a circuit unit of the first region and a circuit unit of the second region, a second power supply trace of the first region and a first side connection line of the second region are located on a same straight line extending along the second direction, a second compensation line of the first region and a second side connection line of the second region are located on a same straight line extending along the second direction, and a power supply connection electrode of the first region and a dummy connection electrode of the second region are located on a same straight line extending along the second direction; in at least one unit row comprising a circuit unit of the first region and a circuit unit of the second region, a power supply connection electrode of the first region and a dummy connection electrode of the second region are located on a same straight line extending along the first direction.

13. The display substrate according to claim 10, wherein at least one circuit unit of the second region further comprises at least two first compensation lines extending along the first direction, the at least two first compensation lines comprise at least one first side compensation line and at least one second side compensation line, a first end of the first side compensation line is connected with the first side connection line, a second end of the first side compensation line extends toward a direction close to the second side connection line, a first end of the second side compensation line is connected with the second side connection line, and a second end of the second side compensation line extends toward a direction close to the first side connection line.

14. The display substrate according to claim 13, wherein in at least one unit row comprising a circuit unit of the first region and a circuit unit of the second region, a first power supply trace of the first region and a first side compensation line of the second region are located on a same straight line extending along the first direction, and a first connection line of the first region and a second side compensation line of the second region are located on a same straight line extending along the first direction.

15. The display substrate according to claim 2, wherein on a plane parallel to the base substrate, the display region further comprises a third region that is not overlapped with orthographic projections of the first connection line and the second connection line on the base substrate, and at least one circuit unit of the third region comprises the first power supply trace and the second power supply trace, and the second power supply trace is connected with in the low-voltage power supply line through a second connection hole.

16. The display substrate according to claim 15, wherein at least one circuit unit of the third region further comprises a power supply connection electrode, the power supply connection electrode is disposed at a side of the second power supply trace away from the data signal line and connected with the second power supply trace, an orthographic projection of the power supply connection electrode on the base substrate is at least partially overlapped with an orthographic projection of the low-voltage power supply line on the base substrate, and the power supply connection electrode is connected with the low-voltage power supply line through the second connection hole.

17. (canceled)

18. The display substrate according to claim 15, wherein at least one circuit unit of the third region further comprises a first compensation line extending along the first direction and a second compensation line extending along the second direction, first compensation lines in circuit units adjacent in the first direction are connected with each other, second compensation lines in circuit units adjacent in the second direction are connected with each other, the first compensation line is connected with the second power supply trace, the second compensation line is connected with the first power supply trace, and the first compensation line is connected with the second compensation line.

19. The display substrate according to claim 18, wherein in at least one unit row comprising a circuit unit of the first region and a circuit unit of the third region, a first connection line of the first region and a first compensation line of the third region are located on a same straight line extending along the first direction; in at least one unit column comprising a circuit unit of the first region and a circuit unit of the third region, a second compensation line of the first region and a second compensation line of the third region are located on a same straight line extending along the second direction.

20. The display substrate according to claim 2, wherein on a plane parallel to the base substrate, the display region further comprises: a second region provided with the second connection line, and a third region that is not overlapped with orthographic projections of the first connection line and the second connection line on the base substrate; in at least one unit row comprising a circuit unit of the first region, a circuit unit of the second region, and a circuit unit of the third region, a first power supply trace of the first region, a first side compensation line in a first compensation line of the second region, and a first power supply trace of the third region are located on a same straight line extending along the first direction, a first connection line of the first region, a second side compensation line in a first compensation line of the second region, and a first compensation line of the third region are located on a same straight line extending along the first direction, a power supply connection electrode of the first region, a dummy connection electrode of the second region, and a power supply connection electrode of the third region are located on a same straight line extending along the first direction; in at least one unit column comprising a circuit unit of the first region, a circuit unit of the second region, and a circuit unit of the third region, a second power supply trace of the first region, a first side connection line in a second connection line of the second region, and a second power supply trace of the third region are located on a same straight line extending along the second direction, a second compensation line of the first region, a second side connection line in a second connection line of the second region, and a second compensation line of the third region are located on a same straight line extending along the second direction, and a power supply connection electrode of the first region, a dummy connection electrode of the second region, and a power supply connection electrode of the third region are located on a same straight line extending along the second direction.

21. The display substrate according to claim 2, wherein the display substrate further comprises a bonding region located at a side of the display region in the second direction, the bonding region at least comprises a bonding lead, a first power supply connection line, and a first power supply pin, a first end of the first power supply connection line is connected with the low-voltage power supply line through a via, a second end of the second power supply connection line, after extending toward a direction away from the display region, is connected with the first power supply pin, and the first power supply pin is connected with the bonding lead through a via;
or,
the display substrate further comprises an upper bezel region located at a side of the display region in an opposite direction of the second direction, the upper bezel region at least comprises an upper bezel lead, a second power supply connection strip, a second power supply connection line, and a second power supply pin, a first end of the second power supply connection strip is connected with the low-voltage power supply line through a via, a second end of the second power supply connection strip is connected with a first end of the second power supply connection line, a second end of the second power supply connection line, after extending toward a direction away from the display region, is connected with the second power supply pin, and the second power supply pin is connected with the upper bezel lead through a via;
or,
the display substrate further comprises a side bezel region located at a side or two sides of the display region in the first direction, wherein the side bezel region at least comprises a side bezel lead, a third power supply connection line, and a third power supply pin, a first end of the third power supply connection line is connected with the power supply trace through a via, a second end of the third power supply connection line, after extending toward a direction away from the display region, is connected with the third power supply pin, and the third power supply pin is connected with the side bezel lead through a via.

22-23. (canceled)

24. The display substrate according to claim 1, wherein the pixel drive circuit at least comprises a storage capacitor and a plurality of transistors; on a plane perpendicular to the base substrate, the drive circuit layer comprises a semiconductor layer, a first conductive layer, a second conductive layer, a third conductive layer, a fourth conductive layer, and a fifth conductive layer disposed sequentially on the base substrate, wherein the semiconductor layer at least comprises active layers of the plurality of transistors, the first conductive layer at least comprises gate electrodes of the plurality of transistors and a first electrode plate of the storage capacitor, the second conductive layer at least comprises a second electrode plate of the storage capacitor, the third conductive layer at least comprises first electrodes and second electrodes of the plurality of transistors, the fourth conductive layer at least comprises the data signal line and the low-voltage power supply line, and the fifth conductive layer at least comprises the data connection line and the power supply trace.

25. The display substrate according to claim 24, wherein the third conductive layer further comprises a first power supply line configured to continuously provide a high power supply voltage signal to the pixel drive circuit, an orthographic projection of the low-voltage power supply line on the base substrate and an orthographic projection of the first power supply line on the base substrate are at least partially overlapped and have a first overlapping area, the orthographic projection of the first power supply line on the base substrate has a first area, and the first overlapping area is greater than 0.8* the first area;
or,
the second conductive layer further comprises a second initial signal line configured to provide a second initial signal to the pixel drive circuit, an orthographic projection of a first connection line in the data connection line on the base substrate and an orthographic projection of the second initial signal line on the base substrate are at least partially overlapped and have a second overlapping area, the orthographic projection of the first connection line on the base substrate has a second area, and the second overlapping area is greater than 0.8* the second area.

26. (canceled)

27. A display apparatus, comprising a display substrate according to claim 1.
